(19) United States
(12) Patent Application Publication
(10) Pub. No.: US 2023/0282751 A1
(43) Pub. Date: Sep. 7, 2023

(54) BOTTOM DIELECTRIC ISOLATION AND METHODS OF FORMING THE SAME IN FIELD-EFFECT TRANSISTORS

(71) Applicant: TAIWAN SEMICONDUCTOR MANUFACTURING COMPANY, LTD., HSINCHU (TW)

(72) Inventors: Chia-Cheng Chen, Hsin-Chu City (TW); Yun Chen Teng, New Taipei City (TW); Liang-Yin Chen, Hsinchu City (TW); Yee-Chia Yeo, Hsinchu City (TW); Tsai-Jung Ho, Changhua County (TW)

(21) Appl. No.: 17/833,440

(22) Filed: Jun. 6, 2022

Related U.S. Application Data
(60) Provisional application No. 63/316,121, filed on Mar. 3, 2022.

(51) Int. Cl. H01L 29/786; H01L 29/06; H01L 29/423; H01L 29/775; H01L 21/02; H01L 29/66

(52) U.S. Cl. CPC H01L 29/78618; H01L 29/0673; H01L 29/42392; H01L 29/78696; H01L 29/775; H01L 21/02603; H01L 21/02532; H01L 29/66545; H01L 29/66553; H01L 29/66742; H01L 29/66439

(57) ABSTRACT

A semiconductor structure includes a substrate and a stacked structure including channel layers interleaved with a metal gate structure. The semiconductor structure also includes an isolation feature disposed between the stacked structure and the substrate, where a bottommost portion of the metal gate structure directly contacts the isolation feature. The semiconductor structure further includes a source/drain feature disposed adjacent the stacked structure and an inner spacer disposed between the metal gate structure and the source/drain feature.

### CROSS-REFERENCE TO RELATED APPLICATIONS

This is a non-provisional application of and claims priority to U.S. Provisional Patent Application Ser. No. 63/316,121, filed on Mar. 3, 2022, and titled “Bottom Dielectric Isolation and Methods of Forming the Same in Field-Effect Transistors,” the entire disclosure of which is incorporated herein by reference.

### BACKGROUND

The semiconductor industry has experienced rapid growth. Technological advances in semiconductor materials and design have produced generations of semiconductor devices where each generation has smaller and more complex circuits than the previous generation. In the course of integrated circuit (IC) evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. But these advances have also increased the complexity of processing and manufacturing semiconductor devices.

Multi-gate transistors, such as gate-all-around (GAA) field-effect transistors (FETs), have been incorporated into various memory and core devices to reduce IC chip footprint while maintaining reasonable processing margins. In existing implementations, isolation structures in FETs may be formed by a doped layer within a device substrate to prevent punch-through of leakage current, which has been generally adequate. However, sub-channel leakage control remains a challenge for GAA FETs, especially in advanced generations of devices with scaled architecture. Thus, for at least this reason, improvements in methods of forming isolation structures for mitigating sub-channel leakage issues in GAA FETs are desired.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B illustrate a flowchart of an example method for fabricating a semiconductor device according to various embodiments of the present disclosure.

FIG. 2 is a three-dimensional perspective view of an example semiconductor device according to various embodiments of the present disclosure.

FIGS. 3A, 4A, 5A, 7A, 8A, 9A, 11A, 15A, 16A, 18A, 19A, and 22A are three-dimensional perspective views of the semiconductor device shown in FIG. 2 at intermediate stages of the example methods of FIGS. 1A and/or 1B according to various embodiments of the present disclosure.

FIGS. 6A, 17A, and 23A are planar top views of the semiconductor device shown in FIG. 2 at intermediate stages of the example methods of FIGS. 1A and/or 1B according to various embodiments of the present disclosure.

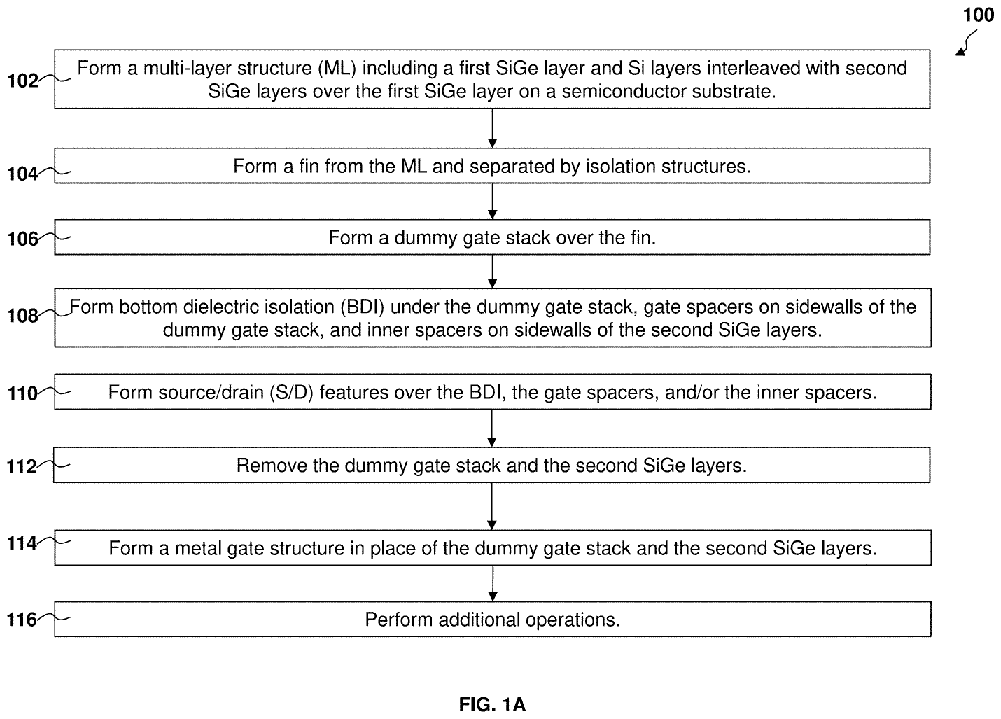

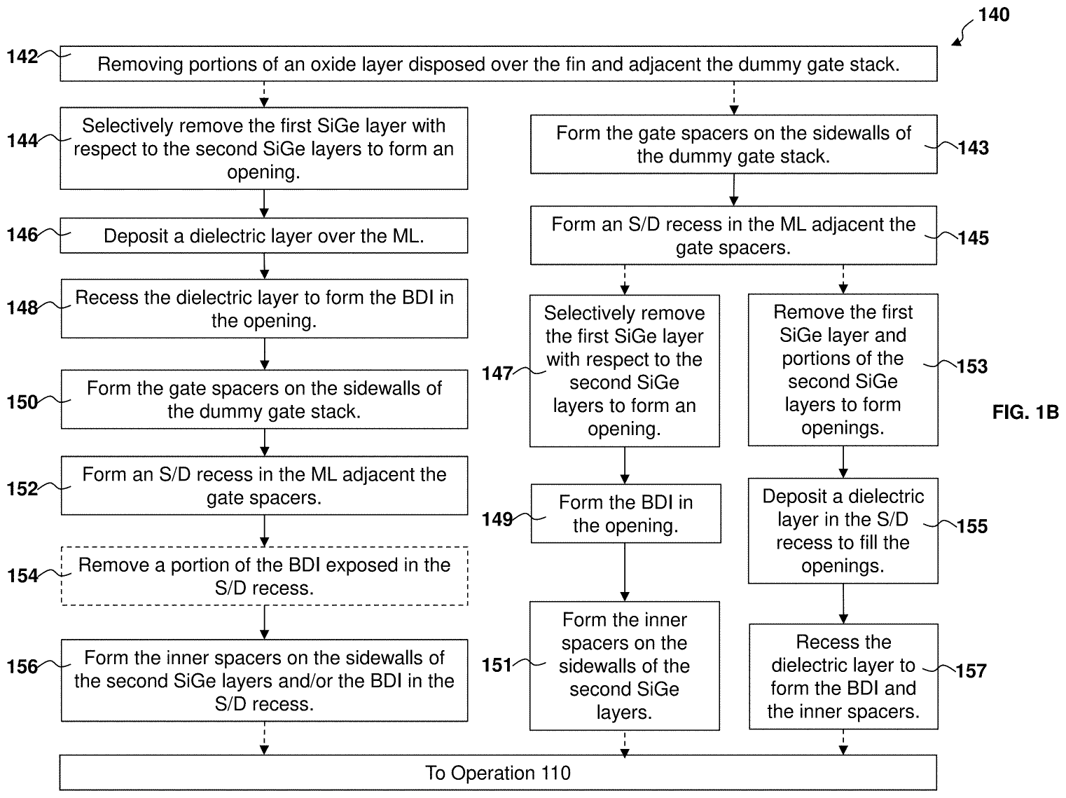

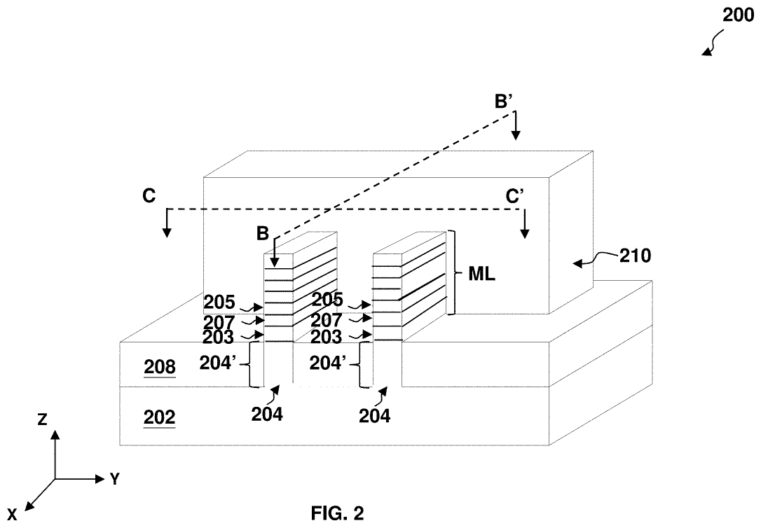

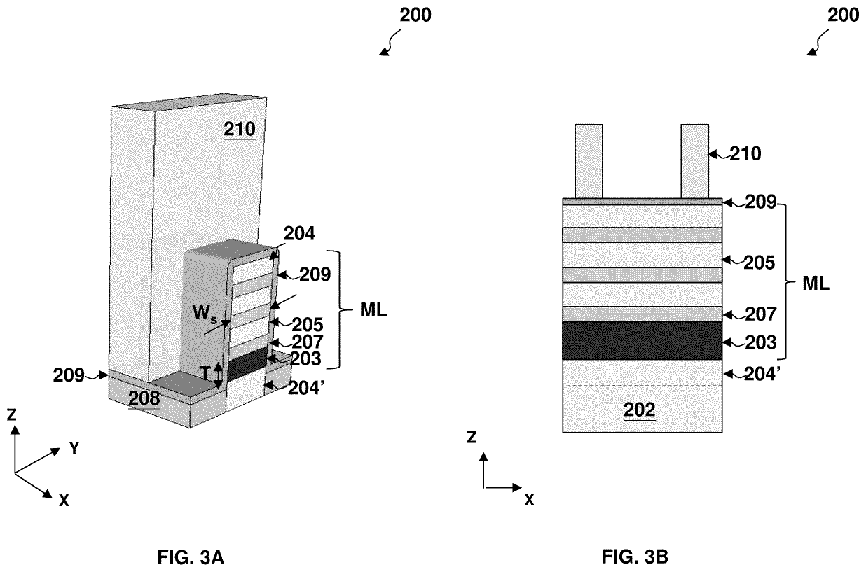

FIGS. 3B, 4B, 5B, 7B, 8B, 9B, 10A, 10B, 10C, 11B, 11C, 12A, 12B, 12C, 13, 14A, 14B, 15B, 16B, 18B, 19B, 20A, 20B, 20C, 21, 22B, 24A, 24B, 25, 26, 27, 28, and 29 are cross-sectional views of the semiconductor device shown in FIG. 2 taken along line BB′ at intermediate stages of the example methods of FIGS. 1A and/or 1B according to various embodiments of the present disclosure.

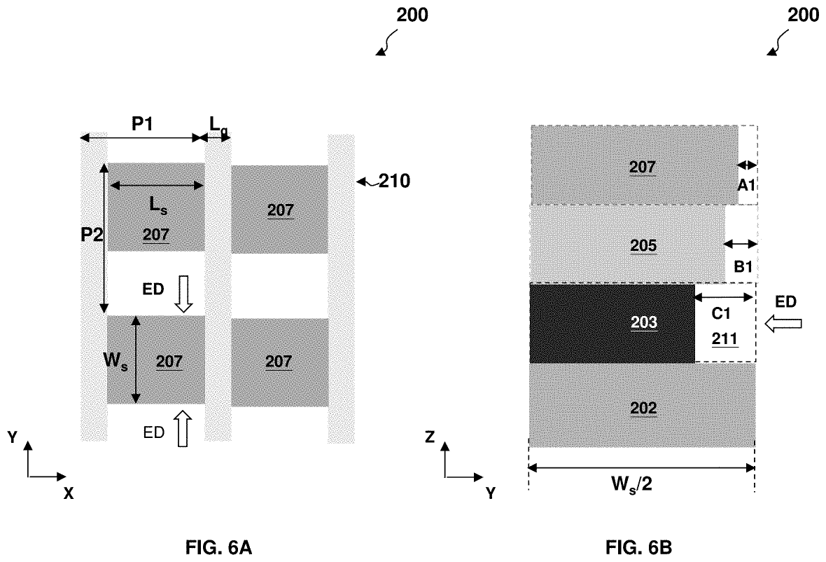

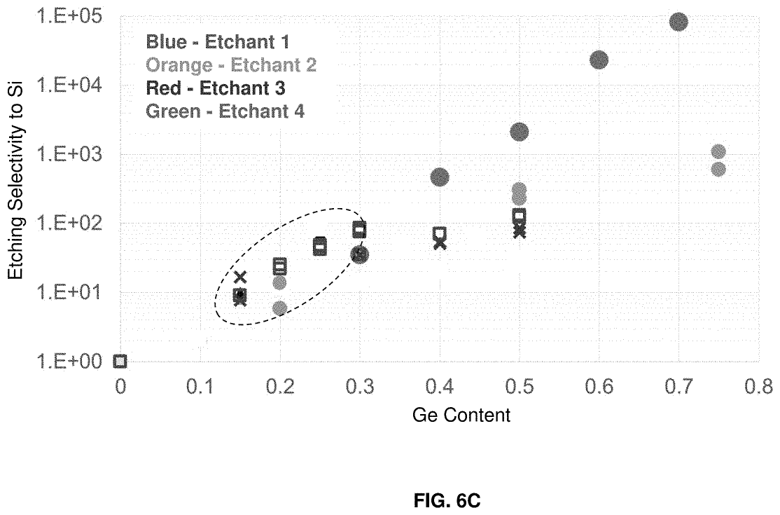

FIGS. 6B, 17B, and 23B are cross-sectional views of the semiconductor device shown in FIG. 2 taken along line CC′ at intermediate stages of the example methods of FIGS. 1A and/or 1B according to various embodiments of the present disclosure.

FIG. 6C is a schematic illustration of a relationship between etching selectivity and Ge content of an embodiment of the semiconductor device being etched using different etchants according to various embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features.

Furthermore, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm. Still further, the present disclosure may repeat reference numerals and/or letters in the various examples. This repetition is for the purpose of simplicity and clarity and does not in itself dictate a relationship between the various embodiments and/or configurations discussed.

The present disclosure is generally directed to structures of and methods of forming multi-gate metal-oxide-semiconductor field-effect transistors (MOSFETs or FETs in the present disclosure), such as gate-all-around (GAA) FETs. More specifically, the present disclosure is directed to structures of and methods of forming multi-layer channel regions in n-channel or n-type GAA FETs (GAA NFETs) and p-channel or p-type GAA FETs (GAA PFETs) that together form a complementary MOSFET (CMOSFET). The GAA FETs provided herein may be nanosheet-based FETs, nanowire-based FETs, and/or nanorod-based FETs. In other words, the present disclosure does not limit the GAA FETs to have a specific configuration.

Generally, the channel region of a GAA NFET and the channel region of a GAA PFET each include a stack of silicon-based channel layers (Si layers) interleaved with a metal gate structure. While such structures are generally adequate for maintaining performance of the GAA devices, they are not entirely satisfactory in all aspects. For example, in existing implementations, isolation structures in FETs may be formed by punch-through stopper implantation, which has been generally adequate. However, sub-channel leakage control remains a challenge for GAA FETs, especially in advanced generations of devices with scaled architecture. The present embodiments provide methods of forming a bottom dielectric isolation structure below a channel and/or a source/drain region of a GAA FET for purposes of mitigating sub-channel leakage issues.

Referring now to FIGS. 1A and 1B, flowchart of method 100 and method 140 of forming a semiconductor device (hereafter referred to as the device) 200 are illustrated according to various aspects of the present disclosure. Methods 100 and 140 are merely examples and are not intended to limit the present disclosure beyond what is explicitly recited in the claims. Additional operations can be provided before, during, and after methods 100 and 140, and some operations described can be replaced, eliminated, or moved around for additional embodiments of each method. Methods 100 and 140 are described below in conjunction with FIGS. 2-28. Specifically, FIGS. 2, 3A, 4A, 5A, 7A, 8A, 9A, 11A, 15A, 16A, 18A, 19A, and 22A are three-dimensional perspective views of the device 200 at intermediate stages of the methods 100 and/or 140; FIGS. 6A, 17A, and 23A are planar top views of the device 200 at intermediate stages of the methods 100 and/or 140. FIGS. 3B, 4B, 5B, 7B, 8B, 9B, 10A, 10B, 10C, 11B, 11C, 12A, 12B, 12C, 13, 14A, 14B, 15B, 16B, 18B, 19B, 20A, 20B, 20C, 21, 22B, 24A, 24B, 25, 26, 27, 28, and 29 are cross-sectional views of the device 200 shown in FIG. 2 taken along line BB′ at intermediate stages of the methods 100 and/or 140; and FIGS. 6B, 17B, and 23B are cross-sectional views of the device 200 shown in FIG. 2 taken along line CC′ at intermediate stages of the methods 100 and/or 140.

The device 200 may be an intermediate device fabricated during processing of an IC, or a portion thereof, that may comprise static random-access memory (SRAM) and/or other logic circuits, passive components such as resistors, capacitors, and inductors, and active components such as GAA FETs, FinFETs, MOSFETs, CMOSFETs, bipolar transistors, high voltage transistors, high frequency transistors, and/or other transistors. The present disclosure is not limited to any particular number of devices or device regions, or to any particular device configurations. Additional features can be added to the device 200, and some of the features described below can be replaced, modified, or eliminated in other embodiments of the device 200.

Referring to FIGS. 1A, 2, and 3A, method 100 at operation 102 provides a semiconductor substrate (hereafter referred to as “the substrate”) 202 and subsequently forms a multilayered structure (ML) thereover. The substrate 202 may include an elemental (i.e., having a single element) semiconductor, such as silicon (Si), germanium (Ge), or other suitable materials; a compound semiconductor, such as silicon carbide, gallium arsenic, gallium phosphide, indium phosphide, indium arsenide, indium antimonide, other suitable materials, or combinations thereof; an alloy semiconductor, such as SiGe, GaAsP, AlInAs, AlGaAs, GaInAs, GaInP, GaInAsP, other suitable materials, or combinations thereof. The substrate 202 may be a single-layer material having a uniform composition. Alternatively, the substrate 202 may include multiple material layers having similar or different compositions suitable for manufacturing the device 200.

In some examples where the substrate 202 includes FETs, various doped regions may be disposed in or on the substrate 202. The doped regions may be doped with n-type dopants, such as phosphorus or arsenic, and/or p-type dopants, such as boron or BF₂, depending on design requirements. The doped regions may be formed directly on the substrate 202, in a p-well structure, in an n-well structure, in a dual-well structure, or in a raised structure. Doped regions may be formed by implantation of dopant atoms, in-situ doped epitaxial growth, and/or other suitable techniques. Of course, these examples are for illustrative purposes only and are not intended to be limiting.

In the present embodiments, the ML includes alternating silicon germanium (SiGe) and silicon (Si) layers arranged in a vertical stack along the Z axis and is configured to provide channel regions suitable for forming a GAA FET, such as a GAA NFET or a GAA PFET. In the depicted embodiments, the bottommost layer of the ML is a SiGe layer 203 and the subsequent layers of the ML include alternating SiGe layers 207 and Si layers 205, where the Si layers 205 are configured as the channel layers of the GAA FET and the SiGe layers 207 are considered non-channel layers to be replaced with a metal gate structure. In the present embodiments, the ML includes the same number of the Si layers 205 as the SiGe layers 207. In some examples, the ML may include three to ten Si layers 205 and, accordingly, three to ten SiGe layers 207. In the present embodiments, the ML includes only one SiGe layer 203 in the bottommost portion of the ML.

In the present embodiments, each Si layer 205 includes elemental Si and is substantially free of Ge, while the SiGe layer 203 and each SiGe layer 207 substantially include both Si and Ge, though the amount of Ge in the SiGe layer 203 is greater than that in each SiGe layer 207. In the present embodiments, the SiGe layer 207 has a composition that may be expressed as Si₁₋ₓGeₓ, where x (or the amount of Ge) is at least about 0.15 (15%) but less than about 0.3 (30%), and accordingly, (1-x) is at least about 0.7 (70%) but less than about 0.85 (85%). The SiGe layer 203, on the other hand, has a composition that may be expressed as Si_{1-y}Ge_{y}, where y (or the amount of Ge) is generally greater than x. In the present embodiments, y is at least about 0.3 (30%) but does not exceed about 0.6 (60%). By comparison, the amount of Si in each Si layer 205 is at least about 0.95 (95%).

With respect to the Si layers 205, a minimum amount of Ge at about 15% in the SiGe layers 203 and 207 provides sufficient selectivity during an etching process to remove or release the channel layers, i.e., the Si layer 205, when forming the GAA FET. In other words, if the amount of Ge in the SiGe layers 207 (and 203) is less than about 15%, the Si layers 205 may be inadvertently damaged during the channel (or sheet) release process. On the other hand, according to some embodiments, a difference in the amount of Ge between the SiGe layers 203 and 207 provides selectivity during an etching process to selectively remove the SiGe layer 203 with respect to the SiGe layers 207 for forming a bottom (or buried) dielectric isolation structure (BDI) below the ML. In other words, if the amount of Ge in the SiGe layer 203 is similar to that of the SiGe layers 207, the SiGe layers 207 may be inadvertently damaged when forming the BDI. Because the SiGe layers 207 are configured to be replaced with a metal gate structure and inner spacers, the etching selectivity between the SiGe layer 203 and the SiGe layers 207 may vary based on a desired thickness of the resulting inner spacers. In some embodiments, adjusting the etching selectivity between the SiGe layer 203 and the SiGe layers 207 may affect structure of the resulting BDI as discussed in detail below.

In the present embodiments, forming the ML includes alternatingly growing a SiGe layer (i.e., the SiGe layer 203 or the SiGe layer 207) and a Si layer (i.e., the Si layer 205) in a series of epitaxy growth processes implementing chemical vapor deposition (CVD) techniques (for example, vapor-phase epitaxy (VPE), ultra-high vacuum CVD (UHV-CVD), low-pressure CVD (LP-CVD), and/or plasma-enhanced CVD (PE-CVD)), molecular beam epitaxy, other suitable selective epitaxial growth (SEG) processes, or combinations thereof. The epitaxy process may use a gaseous and/or liquid precursor that interacts with the composition of the underlying substrate. For example, the substrate 202, which includes Si, may interact with a Ge-containing precursor to form the SiGe layer 203 and the SiGe layer 207. In some examples, the SiGe layer 203, the Si layers 205, and the SiGe layers 207 may be formed into nanosheets, nanowires, or nanorods.

In some embodiments, referring to FIG. 3A, the SiGe layer 203 is formed to a thickness T measured along the Z axis that is greater than a thickness of the Si layer 205 and the SiGe layer 207. In some embodiments, the thickness T is similar to that of the Si layer 205 and the SiGe layer 207. In some embodiments, the SiGe layer 203, the Si layers 205, and the SiGe layers 207 are formed to a width Wₛ measured along the Y axis, where Wₛ does not exceed about 40 nm. In some examples, the width Wₛ is less than or equal to about 30 nm.

In the present embodiments, the Si layers 205 are configured as channel layers for forming the FET of the device 200, while the SiGe layers 207 are considered the non-channel layers. A sheet (or wire) release process may be implemented after forming epitaxial source/drain (S/D) features, for example, to form multiple openings between the channel layers, and a metal gate structure is subsequently formed in the openings to complete fabrication of the FET. Furthermore, the SiGe layer 203 is configured as a placeholder (or dummy) layer for forming the BDI over a channel region and/or the S/D regions of the FET. Source/drain may refer to a source or a drain, individually or collectively, depending upon the context.

Still referring to FIGS. 1A, 2, and 3A, method 100 at operation 104 forms the fin 204 extending from the substrate 202. In the depicted embodiments, the fin 204 is oriented lengthwise along the X axis. Depending on the conductivity type of the resulting FET, the fin 204 may be formed in a region of the substrate 202 doped with a p-type dopant (i.e., a p-well structure) to form an NFET or formed in a region of the substrate 202 doped with an n-type dopant (i.e., an n-well structure) to form a PFET. It is noted that embodiments of the device 200 may include additional fins (semiconductor fins) disposed over the substrate 202 configured to provide one or more NFETs and/or PFETs.

In the present embodiments, each fin 204 includes the ML disposed over a base fin 204′, where the base fin 204′ protrudes from the substrate 202. The fin 204 may be fabricated using suitable processes including photolithography and etch processes. The photolithography process may include forming a masking element having one or more hard mask layers (not depicted), a photoresist layer (or resist; not depicted) over the hard mask layers, patterning the photoresist layer, and patterning the hard mask layers using the patterned photoresist layer as an etch mask, thereby forming a patterned masking element. The patterned masking element is then used for etching recesses into the ML and portions of the substrate 202, leaving the fin 204, which includes the ML and the base fin 204′, protruding from the substrate 202. The hard mask layers may include silicon oxide, silicon nitride, silicon carbide, silicon oxynitride, silicon oxycarbide, other suitable materials, or combinations thereof. The etching process may include dry etching, wet etching, reactive ion etching (RIE), other suitable processes, or combinations thereof.

Numerous other embodiments of methods for forming the fin 204 may be suitable. For example, the fin 204 may be patterned using double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fin 204.

Still referring to FIGS. 1A, 2, and 3A, method 100 at operation 104 forms isolation structures 208 over the substrate 202 and surrounding a bottom portion of the fin 204. The isolation structures 208 may include silicon oxide, fluoride-doped silicate glass (FSG), a low-k dielectric material, other suitable materials, or combinations thereof. In the present embodiments, the isolation structures 208 include shallow trench isolation (STI) features. In some embodiments, the isolation structures 208 are formed by depositing a dielectric layer over the substrate 202, thereby filling trenches between adjacent fins 204, and subsequently recessing the dielectric layer such that a top surface of the isolation structures 208 is below a top surface of the fin 204. Other isolation structures such as field oxide, local oxidation of silicon (LOCOS), other suitable structures, or combinations thereof may also be implemented as the isolation structures 208. In some embodiments, the isolation structures 208 may include a multi-layer structure, for example, having one or more thermal oxide liner layers. The isolation structures 208 may be deposited by any suitable method, such as CVD, flowable CVD (FCVD), spin-on-glass (SOG), other suitable methods, or combinations thereof.

Referring to FIGS. 1A and 2-3B, method 100 at operation 106 forms a dummy gate stack (i.e., a placeholder gate) 210 over the channel region of each of the fin 204. In the present embodiments, portions of the dummy gate stack 210, which includes polysilicon, are replaced with a high-k (referring to a dielectric material having a dielectric constant greater than that of silicon oxide, which is about 3.9) metal gate structure (hereafter referred to as metal gate structure for short) after forming other components (e.g., the epitaxial S/D features) of the device 200. The dummy gate stack 210 may be formed by a series of deposition and patterning processes. For example, the dummy gate stack 210 may be formed by depositing a polysilicon layer over the fin 204, and subsequently performing an anisotropic etching process (e.g., a dry etching process), leaving portions of the polysilicon over the channel regions of the fin 204. The dummy gate stack 210 may further include and inter facial layer (not depicted separately) and a gate dielectric layer (not depicted separately).

In the present embodiments, method 100 at operation 106 first forms a dummy oxide layer 209 over the substrate 202 before forming the dummy gate stack 210. The dummy oxide layer 209 may include a suitable oxide material, such as silicon oxide, and may be formed by a suitable method, such as thermal oxidation, chemical oxidation, other suitable methods, or combinations thereof.

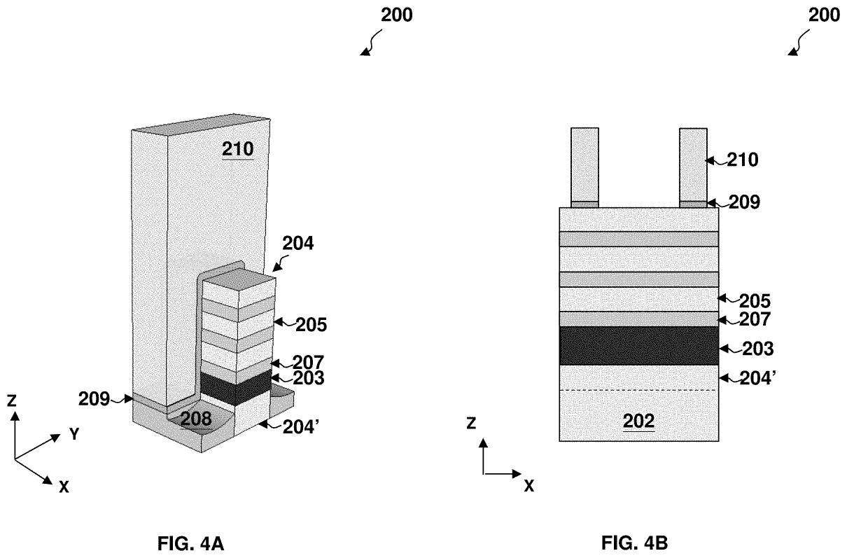

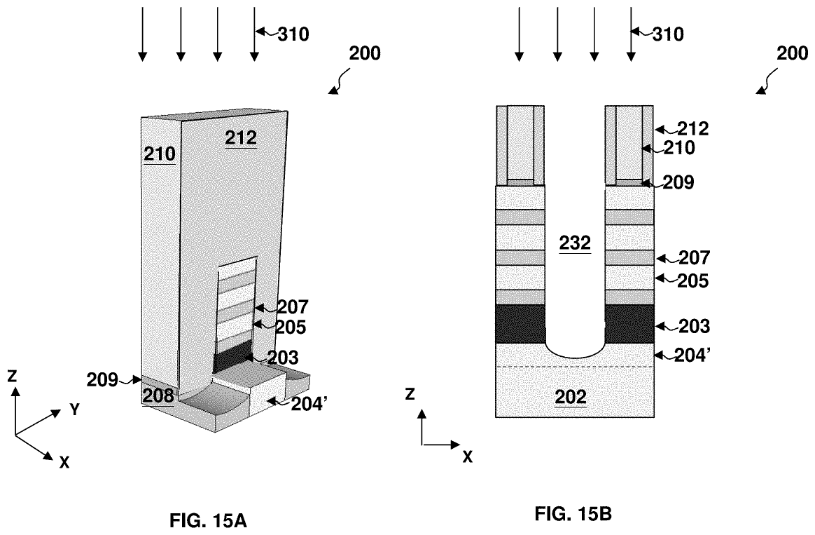

Subsequently, method 100 at operation 108 forms various isolation structures in the device 200. The various isolation structures include, for example, the BDI (e.g., BDI 224, BDI 226, or BDI 276), top gate spacers (e.g., top gate spacers 212), and inner spacers (e.g., inner spacers 240 or inner spacers 242). In the present embodiments, operation 108 is implemented by method 140 as depicted in FIG. 1B. In some embodiments, method 140 may form the BDI before forming an S/D recess (e.g., S/D recess 230 or S/D recess 232) in a BDI-first process illustrated by operations 144-156 in conjunction with FIGS. 4A-12C. Alternatively, method 140 may form the BDI after forming the S/D recess in a BDI-last process illustrated by operations 143-157 in conjunction with FIGS. 15A-24B.

Now referring to FIGS. 1B and 4A-4B, method 140 at operation 142 removes portions of the dummy oxide layer 209 from portions of the device 200 not covered by the dummy gate stack 210. Method 140 may implement an etching process that selectively removes the exposed portions of the dummy oxide layer 209 without removing, or substantially removing, other components of the device 200 including, for example, the dummy gate stack 210, the ML, and the isolation structures 208. The selective etching process may be a dry etching process, a wet etching process, a reactive ion etching (RIE) process, other suitable processes, or combinations thereof.

Referring to FIGS. 1B and 5A-6B, method 140 at operation 144 selectively removes the SiGe layer 203 with respect to the Si layers 205 and the SiGe layers 207 in an etching process 302 to form an opening 211 between a bottom surface of the ML and the substrate 202.

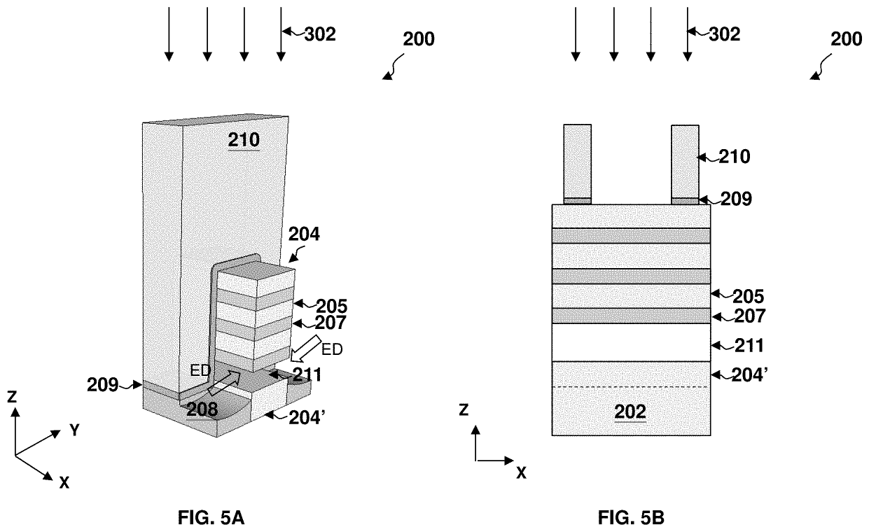

In the present embodiments, referring to FIGS. 5A and 6A, the etching process 302 is configured to remove the SiGe layer 203 isotropically from two opposite directions ED along the Y axis. In other words, the SiGe layer 203 is removed from both sides of the ML. In this regard, referring to FIGS. 6A-6B, a width C1 of the opening 211 is about half of a width Wₛ (i.e., Wₛ/2) of the ML measured along the Y axis. In some embodiments, the etching process 302 may inadvertently remove, though unsubstantially, portions of the SiGe layers 207 and the Si layers 205. As depicted in FIG. 6B, the amount removed from the SiGe layer 207 may be defined by a width A1 and the amount removed from the Si layer 205 may be defined by a width B1, where the width A1 is less than the width B1. Accordingly, an etching selectivity S1 between the SiGe layers 207, which include Si₁₋ₓGeₓ, and the Si layer 205 is defined by a ratio B1/A1 and an etching selectivity S2 between the SiGe layer 203, which includes Si_{1-y}Ge_{y}, and the SiGe layers 207 is defined by a ratio C1/B1.

In the present embodiments, the etching selectivity S1 is configured to be about 8 to about 100 for a value of x that is about 0.15 to about 0.3 to ensure the substantial removal of the SiGe layers 207 with respect to the Si layers (channel layers) 205 during the subsequent sheet release process. If the etching selectivity S1 is less than about 8, the Si layer 205 may be inadvertently etched during the sheet release process as the amount of Si in the SiGe layers 207 approaches that in the Si layers 205. If the etching selectivity S1 is greater than about 100, the etching selectivity S2 may be inadvertently reduced as the amount of Ge in the SiGe layers 207 may approach that of the SiGe layer 203, i.e., the value of x may approach the value of y.

In some embodiments, the width Wₛ may be less than or equal to about 40 nm, a length Lₛ of the ML along the X axis may be less than about 40 nm, a pitch between adjacent fins 204 may be about 70 nm, a gate length L_{g} of the dummy gate stack 210 may be less than or equal to about 14 nm, and a pitch between adjacent dummy gate stacks 210 may be about 44 nm. As a result, the width C1 may be less than or equal to about 20 nm. In some examples, the width B1 is less than or equal to about 1 nm.

In further embodiments, assuming the width B1 is less than or equal to about 1 nm, an etching selectivity S2 is at least about 15 for a value of y that is about 0.3 to about 0.6. Such level of selectivity ensures that the SiGe layer 203 is substantially etched without etching the SiGe layers 207 during the etching process 302. If the etching selectivity S2 is less than about 15, the SiGe layers 207 may be inadvertently damaged during the etching process 302.

The etching process 302 may be implemented using a dry etchant, a wet etchant, or a combination thereof. Examples of the dry etchant include halogen-containing (e.g., fluorine-containing and/or chlorine-containing) gaseous species such as HF, F₂, CF₄, CHₓF_{y} (where x and y are both positive integers and where y=3x), ClF₃, NF₃, SF₆, Cl₂, HCl, and BCl₃, other gaseous species such as H₂, O₂, He, Ar, and N₂, other suitable gaseous species, or combinations thereof. The example dry etchants may be applied at any suitable temperature, such as at room temperature to less than about 800° C., and at any suitable pressure, such as at about 10⁻³ Torr to about atmospheric pressure.

Examples of the wet etchant include alkaline solutions containing ammonium hydroxide (NH₄OH) and hydrogen peroxide (H₂O₂), alkaline solutions containing tetramethylammonium hydroxide (TMAH) and H₂O₂, acidic solutions containing hydrofluoric acid (HF), H₂O₂, and acetic acid (CH₃COOH), acidic solutions containing HF and HNO₃, other suitable solutions, or combinations thereof. In some examples, H₂O₂ may be fully or partially replaced with ozone water in the example wet etchants. The example wet etchants may be applied at any suitable temperature, such as at room temperature to less than about 100° C., and at any suitable pressure, such as at atmospheric pressure.

In the present embodiments, choice(s) of the etchant used for the etching process 302 varies according to the content of Ge in the SiGe layer 203 and in the SiGe layer 207, respectively, for a target range of the etching selectivity S2. Table 1 below details example etchants configured to provide the target range of the etching selectivity S2 (e.g., at least about 15) at various amounts of Ge in the SiGe layer 203. Specifically, Etchant 1 includes 1:1 (28% NH₄OH):(31% H₂O₂), Etchant 2 includes 1:2:3 (20%-50% HF):(30% H₂O₂):(99.5% CH₃COOH), Etchant 3 includes plasmaless ClF₃, and Etchant 4 includes gaseous HCl. The symbol “*” in Table 1 indicates that the example etchant is applicable for selectively etching the SiGe layer 203 at a given composition. For example, Etchant 3 and Etchant 4, alone or in combination, may be used to etch the SiGe layer 203 having at least 50% of Ge. It is noted that the present disclosure is not limited by the content of Table 1, which is provided for purposes of illustration only.

TABLE 1

| | | Etchant 2 | | |
|---|---|---|---|---|
| | Etchant 1 | 1:2:3 (20%-50% | | |
| | 1:1 (28% | HF):(30% | Etchant 3 | Etchant 4 |
| | NH₄OH):(31% | H₂O₂):(99.5% | Plasmaless | Gaseous |
| | H₂O₂) | CH₃COOH) | ClF₃ | HCl |
| x~0.15-0.3 | * | | | |
| y ≥ 0.3 | | | | |
| x~0.15-0.3 | | * | | |
| y ≥ 0.4 | | | | |
| x~0.15-0.3 | | | * | * |
| y ≥ 0.5 | | | | |

FIG. 6C is a schematic illustration of the etching selectivity S1 plotted against the amount of Ge in the SiGe layer 207. Data points of different shapes correspond to different example etchants provided in Table 1 and data points enclosed in the oval indicate the etching selectivity S1 ranging from about 8 to about 100 when the amount of Ge in the SiGe layers 207 is about 15% (0.15) to about 30% (0.3). In other words, the example etchants provided in Table 1 may each be applicable for achieving the target value of the etching selectivity S1 for a given range of Ge content in the SiGe layers 207.

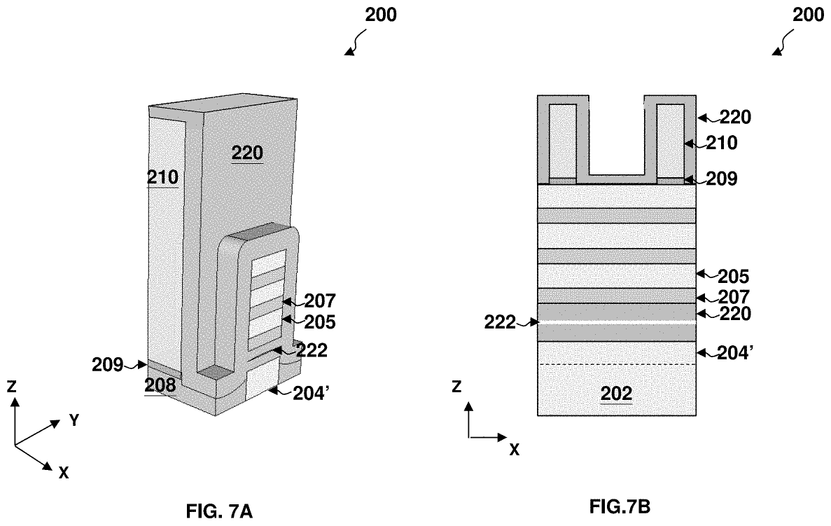

Referring to FIGS. 1B and 7A-7B, method 140 at operation 146 forms a dielectric layer 220 over the device 200. In the present embodiments, the dielectric layer 220 is conformally deposited over the device 200, where a portion of the dielectric layer 220 fills the opening 211. The dielectric layer 220 may include any suitable material, such as silicon oxide, silicon nitride, carbon-containing silicon nitride (SiCN), carbon-containing silicon oxide (SiOC), oxygen-containing silicon nitride (SiON), carbon-and-oxygen-doped silicon nitride (SiOCN), a low-k dielectric material, other suitable dielectric material, or combination thereof.

Method 140 may deposit the dielectric layer 220 by any suitable process, such as an atomic layer deposition (ALD) process, a CVD process, other suitable processes, or combinations thereof. In the present embodiments, the dielectric layer 220 is deposited by an ALD process. In some embodiments, forming the dielectric layer 220 in the opening 211 using the ALD process results in a seam, or an air gap, 222 that extends across a width of the dielectric layer 220 (i.e., along the Y axis) in the opening 211 and along a length of the fin 204 (i.e., along the X axis). In the present embodiments, the seam 222 is substantially horizontal, i.e., substantially along the X axis. In some embodiments, however, the seam 222 does not necessarily appear as a result of the deposition process at operation 146.

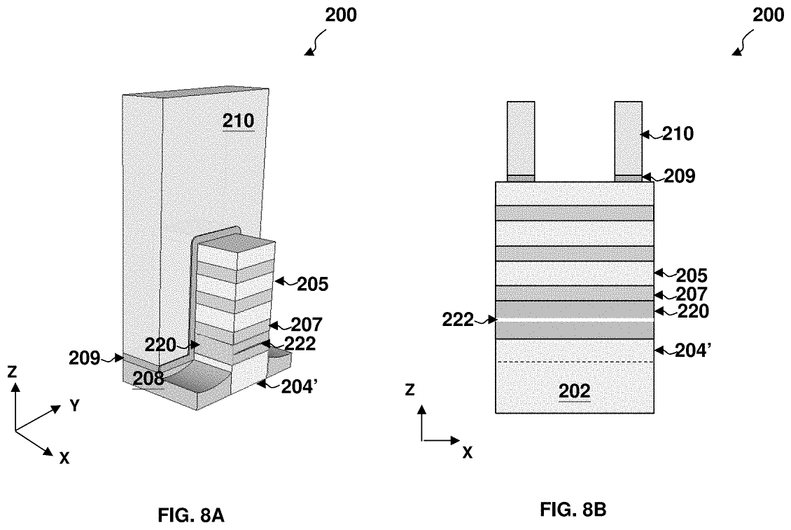

Subsequently, referring to FIGS. 1B and 8A-8B, method 140 at operation 148 removes excess portions of the dielectric layer 220 formed over the dummy gate stack 210 and over exposed surfaces of the fin 204, leaving only the portion formed in the opening 211. Method 140 may remove the excess portions of the dielectric layer 220 by an anisotropic etching process, such as a dry etching process.

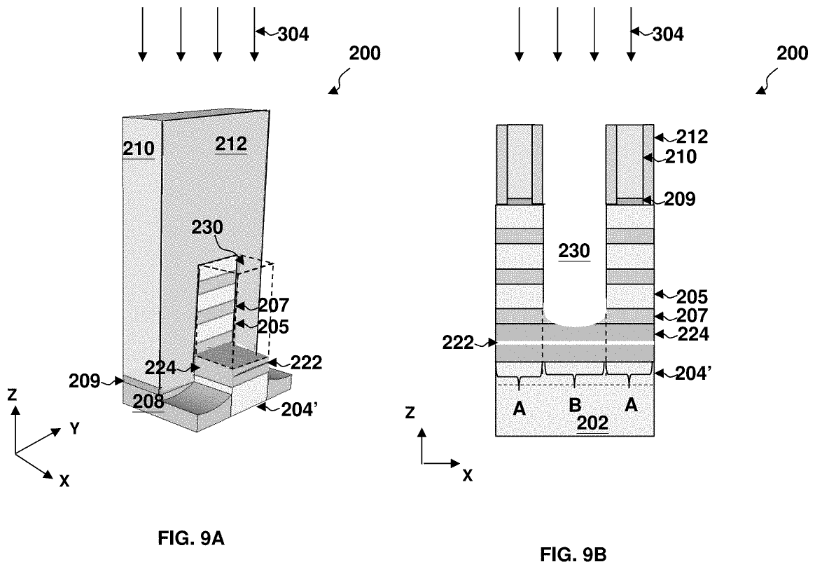

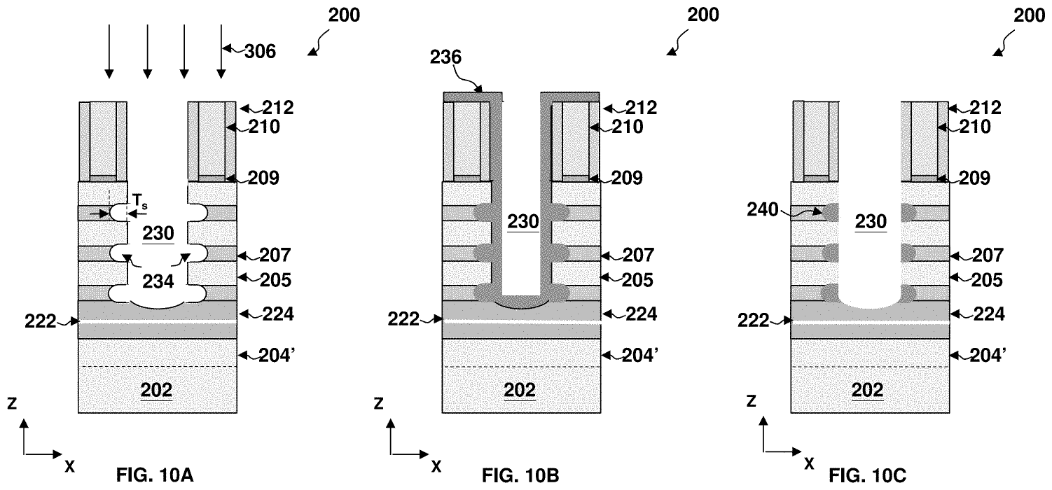

Referring to FIGS. 1B and 9A-9C, method 140 at operation 150 forms top gate spacers 212 on sidewalls of the dummy gate stack 210. The top gate spacers 212 may be a single-layer structure or a multi-layer structure and may include silicon oxide, silicon nitride, silicon carbide, oxygen-containing silicon nitride (SiON), carbon-containing silicon oxide (SiOC), other suitable materials, or combinations thereof. Each spacer layer of the top gate spacers 212 may be formed by first depositing a dielectric layer over the dummy gate stack 210 and subsequently removing portions of the dielectric layer in an anisotropic etching process (e.g., a dry etching process), leaving portions of the dielectric layer on the sidewalls of the dummy gate stack 210 as the top gate spacers 212.

Still referring to FIGS. 1B and 9A-9B, method 140 at operation 152 forms an S/D recess 230 in the S/D region of the fin 204 adjacent the top gate spacer 212. In the present embodiments, method 100 removes portions of the ML in the S/D region of the fin 204 by an etching process 304, which may be a dry etching process, a wet etching process, RIE, or combinations thereof. A cleaning process may subsequently be performed to remove any etching residues in the S/D recess 230 with HF and/or other suitable solvents. In the present embodiments, referring to FIG. 9B, the S/D recess 230 exposes a portion of the dielectric layer 220 to form a BDI 224 that extends over both the channel and the S/D regions of the fin 204. In other words, a first portion A of the BDI 224 is formed over the channel region of the fin 204 (i.e., between a bottommost surface of the subsequently-formed metal gate structure and the substrate 202) and a second portion B of the BDI 224 is formed over the S/D regions of the fin 204 (i.e., between a bottommost surface of the subsequently-formed S/D features and the substrate 202). Accordingly, the BDI 224 is considered a “full BDI” in the present embodiments. In some embodiments, method 140 at operation 152 implements an etchant configured to remove the Si layers 205 and the SiGe layers 207 without removing, or substantially removing, the dielectric layer 220. In this regard, the S/D recess 230 may expose a top surface of the BDI 224 and not extend past the seam 222 as depicted in FIG. 9B.

In some embodiments, referring to FIGS. 1B and 10A-10C, method 140 proceeds from operation 152 to operation 156 to form inner spacers 240 on sidewalls of the SiGe layers 207 (i.e., the non-channel layers) exposed in the S/D recess 230. Referring to FIG. 10A, method 140 selectively removes portions of the SiGe layers 207 exposed in the S/D recess 230 in an etching process 306 to form recesses 234. In the present embodiments, the etching process 306 is selective toward Ge at a content of at least about 15%, i.e., x is at least about 0.15, such that the SiGe layers 207 are etched at a significantly higher rate than the Si layers 205, which are substantially free of Ge. Additionally, the etching process 306 is also selective toward Ge with respect to the dielectric layer 220 (i.e., the BDI 224). In some embodiments, the etching process 306 is a wet etching process that implements H₂O₂, a hydroxide (e.g., NH₄OH, TMAH, etc.), CH₃COOH, other suitable etchants, or combinations thereof. In some embodiments, the etching process 306 is a dry etching process that implements a fluorine-containing gaseous species provided herein. In the present embodiments, the duration of the etching process 306 is controlled to ensure that only portions of each SiGe layer 207 are etched to form the recesses 234, where a width Tₛ of the recess 234 along the X axis defines a thickness of the inner spacer 240 and correspondingly, the gate length L_{g} of the subsequently formed metal gate structure.

Subsequently, referring to FIG. 10B, method 140 deposits a dielectric layer 236 in the recesses 234 via any suitable deposition process, such as ALD, CVD, other suitable methods, or combinations thereof. In the present embodiments, the dielectric layer 236 is conformally deposited over the device 200, such that it is formed on exposed surfaces of the fin 204 and the BDI 224, filling the recesses 234. Referring to FIG. 10C, method 140 then performs one or more etching processes to remove portions of the dielectric layer 236 from the dummy gate stack 210, sidewalls of the top gate spacers 212, and sidewalls of the S/D recess 230, leaving the inner spacers 240 in the recesses 234. As depicted in FIG. 10C, the S/D recess 230 exposes a portion of the BDI 224.

The inner spacers 240 (i.e., the dielectric layer 236) may include any suitable dielectric material comprising silicon, carbon, oxygen, nitrogen, other elements, or combinations thereof. For example, the dielectric layer 236 may include silicon nitride, silicon carbide, silicon oxide, carbon-containing silicon nitride (SiCN), carbon-containing silicon oxide (SiOC), oxygen-containing silicon nitride (SiON), carbon-and-oxygen-doped silicon nitride (SiOCN), a low-k dielectric material, tetraethylorthosilicate (TEOS), doped silicon oxide (e.g., borophosphosilicate glass (BPSG), fluor-doped silicate glass (FSG), phosphosilicate glass (PSG), boron-doped silicate glass (BSG), etc.), air, other suitable dielectric material, or combination thereof. The inner spacers 240 may be configured as a single-layer structure or a multi-layer structure including a combination of the dielectric materials provided herein. In some embodiments, the inner spacers 240 have a different composition from that of the top gate spacers 212. In some embodiments, the inner spacers 240 and the top gate spacers 212 have the same composition. Furthermore, the inner spacers 240 and the BDI 224 may have different compositions.

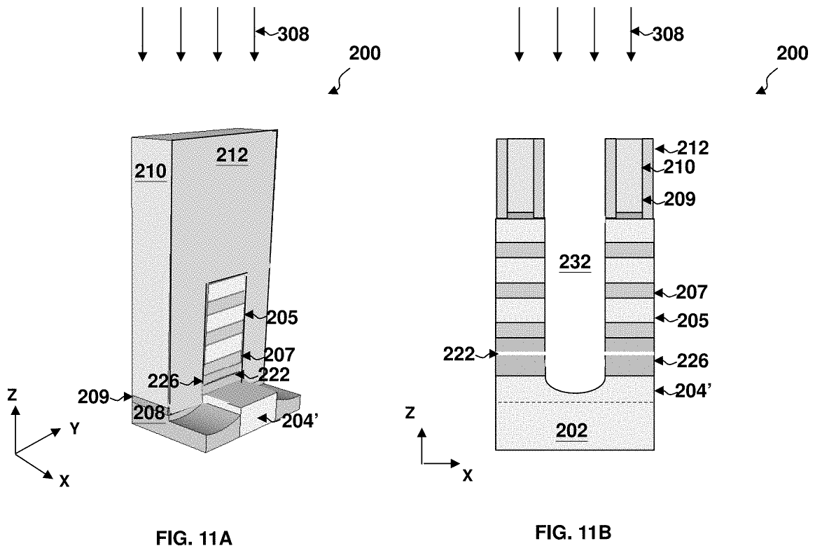

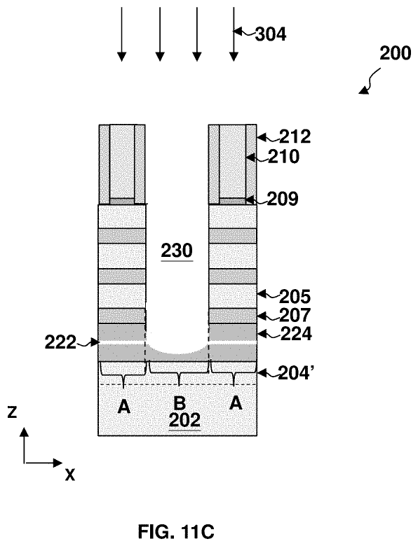

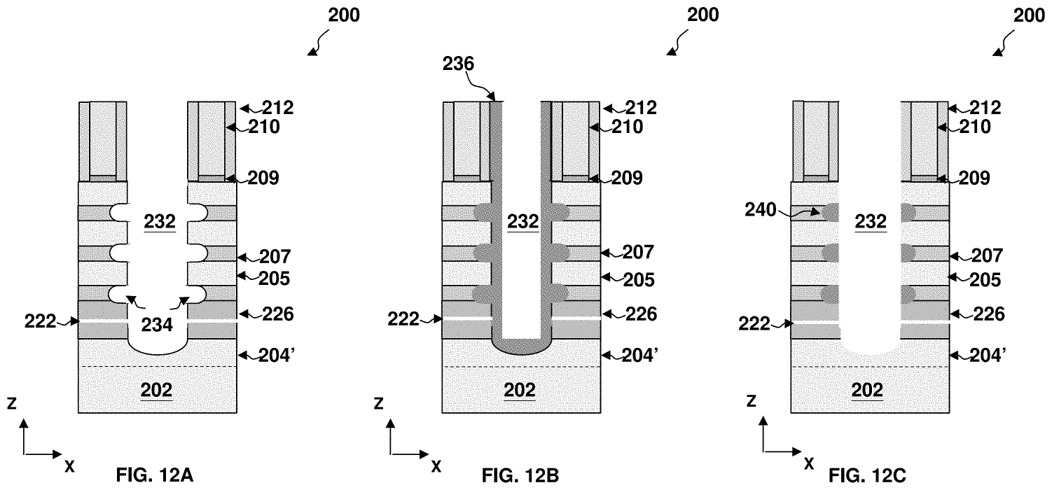

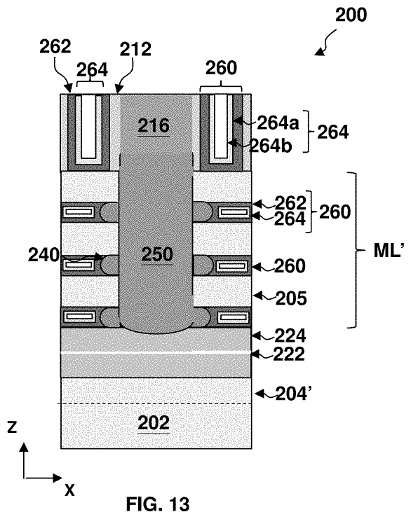

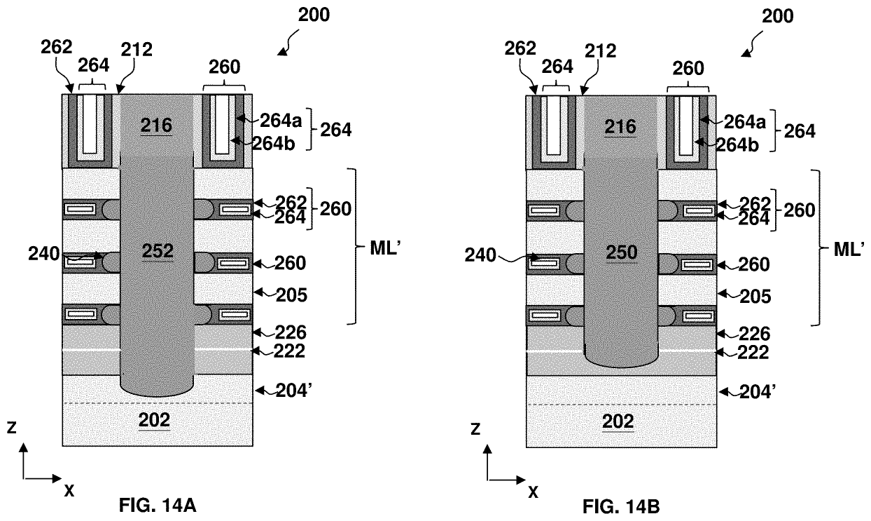

In some embodiments, referring to FIGS. 1B and 11A-11C and before forming the inner spacers 240, method 140 at operation 154 may further remove a portion of the dielectric layer 220 in the S/D region of the fin 204 in an etching process 308. In some embodiments, referring to FIG. 11B, the etching process 308 removes an entirety of the dielectric layer 220 from the S/D regions, such that the portions of the dielectric layer 220 remaining under the channel region of the fin 204 forms a BDI 226. Accordingly, the BDI 226 is considered a “partial BDI” in contrast to the BDI 224 depicted in FIGS. 9A-10C. In some embodiments, referring to FIG. 11C, the etching process 308 removes a portion of the dielectric layer 220, such that a portion of the dielectric layer 220 remains over the S/D regions to form the BDI 224, i.e., the “full BDI,” similar to that depicted in FIGS. 9A-10C. In other words, the S/D recess 230 may extend to above (not depicted) or below the seam 222 (as depicted in FIG. 11C for example) without exposing the fin 204 in the S/D regions. Similar to the embodiment depicted in FIG. 9B, the BDI 224 may include the first portion A over the S/D regions and the second portion B over the channel region of the fin 204. In some embodiments, operation 154 may be omitted and the BDI 224 remains over both the channel and the S/D regions of the fin 204.

The etching process 308 differs from the etching process 304 in that the etching process 308 is selective to remove the dielectric layer 220 and is not configured to remove, or substantially remove, the Si layers 205, the SiGe layers 207, or other components of the device 200. In some embodiments, the etching process 308 is an anisotropic etching process, such as a dry etching process, and may be controlled by etching duration or by end-point detection. For example, with respect to forming the BDI 226 as depicted in FIG. 11B, the etching process 308 is controlled such that the S/D recess 230 is extended along the Z axis to expose the substrate 202 (or the base fin 204′) in an S/D recess 232. With respect to forming the BDI 224 as depicted in FIG. 11C, the etching process 308 is controlled such that the S/D recess 230 only partially penetrate the dielectric layer 220 to stop between the seam 222 and the substrate 202.

Subsequently, referring to FIGS. 1B and 12A-12C, method 140 at operation 156 forms the inner spacers 240 on the exposed sidewalls of the SiGe layers 207 in a series of processes similar to those depicted in FIGS. 10A-10C. Notably, owing to the “partial” structure of the BDI 226, the S/D recess 232 exposes a portion of the substrate 202 rather than the BDI 224 as depicted in FIG. 10C.

Thereafter, referring to FIGS. 1A and 13-14, method 100 proceeds from operation 108 to operation 110 to form an epitaxial S/D feature in the S/D recess. FIG. 13 depicts an embodiment of the device 200 that includes the BDI 224, or the full BDI, disposed below an epitaxial S/D feature 250 and FIG. 14 depicts an embodiment of the device that include the BDI 226, or the partial BDI, disposed adjacent an epitaxial S/D feature 252. The epitaxial S/D features 250 and 252 may each be configured as an n-type epitaxial S/D feature or a p-type epitaxial S/D feature for forming an NFET or a PFET, depending on specific design requirement. The epitaxial S/D features 250 and 252 may each include one or more epitaxial layers of silicon (epi Si) or silicon carbon (epi SiC) doped with an n-type dopant such as arsenic, phosphorus, other n-type dopants, or combinations thereof to form an n-type epitaxial S/D feature. Alternatively, the epitaxial S/D features 250 and 252 may each include one or more epitaxial layers of silicon germanium (epi SiGe) doped with a p-type dopant such as boron, germanium, indium, other p-type dopants, or combinations thereof to form a p-type epitaxial S/D feature.

Method 100 may form the epitaxial S/D features 250 and 252 by implementing an epitaxy growth process as discussed above with respect to forming various layers of the ML. In some embodiments, the epitaxial material is doped in-situ by adding a dopant to a source material during the epitaxy growth process. In some embodiments, the epitaxial material is doped by an ion implantation process after performing a deposition process. In some embodiments, an annealing process is subsequently performed to activate the dopants in the epitaxial S/D features 250 and 252.

Still referring to FIGS. 1A and 13-14B, method 100 at operation 112 removes the dummy gate stack 210 and the SiGe layers 207. FIG. 13 corresponds to the embodiment depicted in FIGS. 9A-10C, FIG. 14A corresponds to the embodiment depicted in FIGS. 11A, 11B, and 12A-12C, and FIG. 14B corresponds to the embodiment depicted in FIG. 11C. Before removing the dummy gate stack 210, method 100 forms an interlayer dielectric (ILD) layer 216 over the epitaxial S/D feature 250 (or 252), which may include silicon oxide, a low-k dielectric material, TEOS, doped silicon oxide (e.g., BPSG, FSG, PSG, BSG, etc.), other suitable dielectric materials, or combinations thereof. In some embodiments, method 100 may form an etch-stop layer (ESL) over the epitaxial S/D features 250 (or 252) before forming the ILD layer 216. The ESL may include silicon nitride, silicon carbide, carbon-containing silicon nitride (SiCN), oxygen-containing silicon nitride (SiON), carbon-and-oxygen-doped silicon nitride (SiOCN), aluminum nitride, a high-k dielectric material, other suitable materials, or combinations thereof. The ILD layer 216 and the ESL may each be formed by CVD, FCVD, ALD, PVD, other suitable methods, or combinations thereof. After planarizing the ESL and the ILD layer 216 in one or more CMP processes, at least portions of the dummy gate stack 210 are removed from the device 200 to form a gate trench (not depicted) by any suitable etching process, such as a dry etching process. In some embodiments, the dummy oxide layer 209 is removed from the gate trench and replaced with an interfacial layer (not depicted) before forming the metal gate structure in the gate trench.

Subsequently, method 100 at operation 112 performs the sheet release process to form openings (not depicted) between the Si layers 205 in the fin 204. The sheet release process may be implemented by an etching process that does not, or does not substantially, remove the Si layers 205 and other surrounding dielectric features of the device 200. As discussed in detail above, a minimum Ge content of about 15% ensures sufficient etching selectivity S1 (e.g., about 8 to about 100 as discussed in detail above) for removing the SiGe layers 207 without damaging the Si layers 205. The etching process may be a dry etching process or a wet etching process selective to Ge included in the SiGe layers 207. The resulting openings provide space for forming the metal gate structure between the channel layers, i.e., the Si layers 205. In this regard, the terms “channel layers 205” and “Si layers 205” are interchangeable in the following discussion.

Example dry and wet etchants that may be used to selectively etch the SiGe layers 207 with respect to the Si layers 205 are discussed in detail above (see Table 1, for example). With respect to the dry etchants, halogen-containing (e.g., fluorine-containing and/or chlorine-containing) gaseous species may preferentially react with Si—Ge bonds than with Si—Si bonds to form Si—F bonds, Ge—F bonds, and reactive dangling bonds, which may further facilitate reactions with additional halogen atoms to completely remove the SiGe layers 207. With respect to alkaline-based wet etchants, although both the Si layers 205 and the SiGe layers 207 may be oxidized by an oxidizer (e.g., H₂O₂, HNO₃, and ozone water) to form Si(OH)₂ and Ge(OH)₂²⁺, respectively, the rates at which Si(OH)₂ and Ge(OH)₂²⁺ are dissolved by hydroxide OH⁻ ions may be tuned to achieve a target range of the etching selectivity S1. Similarly, as the Si layers 205 and the SiGe layers 207 may both be oxidized by an oxidizer and subsequently dissolved by an acid, such as HF, in an acid-based wet etchant, the etching selectivity S1 may be tuned by adjusting a ratio (by weight or by volume) of the oxidizer to the acid.

Thereafter, still referring to FIGS. 1A and 13-14, method 100 at operation 114 forms a metal gate structure 260 in the gate trench and the openings to replace the dummy gate stack 210 and the SiGe layers 207, respectively. As a result, a portion of the metal gate structure 260 wrap around and engage with each channel layer 205 to form a stacked structure ML′. In the present embodiments, the metal gate structure 260 include at least a high-k dielectric layer 262 disposed over and surrounding the channel layers 205 and a metal gate electrode 264 disposed over the high-k dielectric layer 262. In the present embodiments, the high-k dielectric layer 262 includes any suitable high-k dielectric material, such as hafnium oxide, lanthanum oxide, other suitable materials, or combinations thereof. In the present embodiments, the metal gate electrode 264 includes at least a work function metal (WFM) layer 264a disposed over the high-k dielectric layer 262 and a conductive layer (or metal fill layer) 264b disposed over the WFM layer. The WFM layer 264a may be a single-layer structure or a multi-layer structure including at least a p-type WFM layer, an n-type WFM layer, or a combination thereof. The conductive layer 264b may include Cu, W, Al, Co, Ru, other suitable materials, or combinations thereof. The metal gate structure 260 may further include other layers (not depicted), such as a capping layer, a barrier layer, other suitable layers, or combinations thereof. Various layers of the metal gate structure 260 may be formed by any suitable method, such as chemical oxidation, thermal oxidation, ALD, CVD, PVD, plating, other suitable methods, or combinations thereof.

Alternative to the example BDI-first process discussed above with respect to FIGS. 5A-12C, method 140 may implement a BDI-last process during which the BDI is formed after forming the S/D recess. In some embodiments, a partial BDI (i.e., the BDI 226) is formed separately from the inner spacers (i.e., the inner spacers 240), as illustrated by operations 147, 149 and 151 in FIGS. 15A-20C. In some embodiments, the partial BDI is formed together with the inner spacers, as illustrated by operations 153, 155, and 157 in FIGS. 15A-15B and 22A-24B.

Referring to FIGS. 1B and 15A-15B, after removing portions of the dummy oxide layer 209 from the device 200 at operation 142, method 140 at operation 143 forms the top gate spacers 212 on the sidewalls of the dummy gate stack 210 in a process similar to that of operation 150 discussed above with respect to FIGS. 9A-9B.

Still referring to FIGS. 1B and 15A-15B, method 140 at operation 145 implements an etching process 310 to form the S/D recess 232 in the fin 204, where the S/D recess 232 exposes the substrate 202 (or the base fin 204′). In the present embodiments, the etching process 310 differs from the etching processes 304 and 308 in that the etching process 310 is configured to remove the SiGe layer 203, the Si layers 205, and the SiGe layer 207. In contrast, the etching process 304 is configured to selectively remove the Si layers 205 and the SiGe layers 207 without removing, or substantially removing, the dielectric layer 220, and the etching process 308 is configured to substantially remove only the dielectric layer 220.

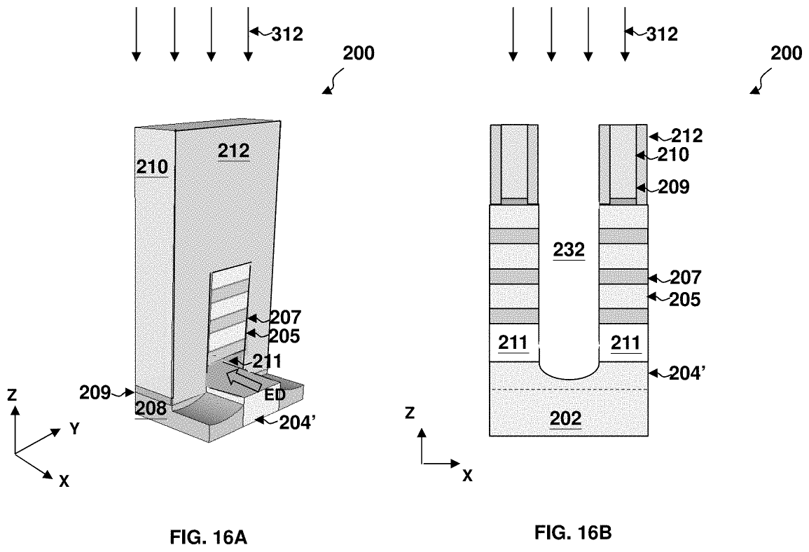

Referring to FIGS. 1B and 16A-16B, method 140 at operation 147 selectively removes the SiGe layer 203 in an etching process 312 to form the opening 211 between the ML and the base fin 204′. In the present embodiments, the etching process 312 is configured to remove the SiGe layer 203 without removing, or substantially removing, the Si layers 205 and the SiGe layers 207. In other words, the etching process 312 removes the SiGe layer 203 at a rate higher than the Si layers 205 and the SiGe layers 207. In some embodiments, the etching process 312 is implemented with one or more etchants that are similar to that used in the etching process 302 (see Table 1 for detail).

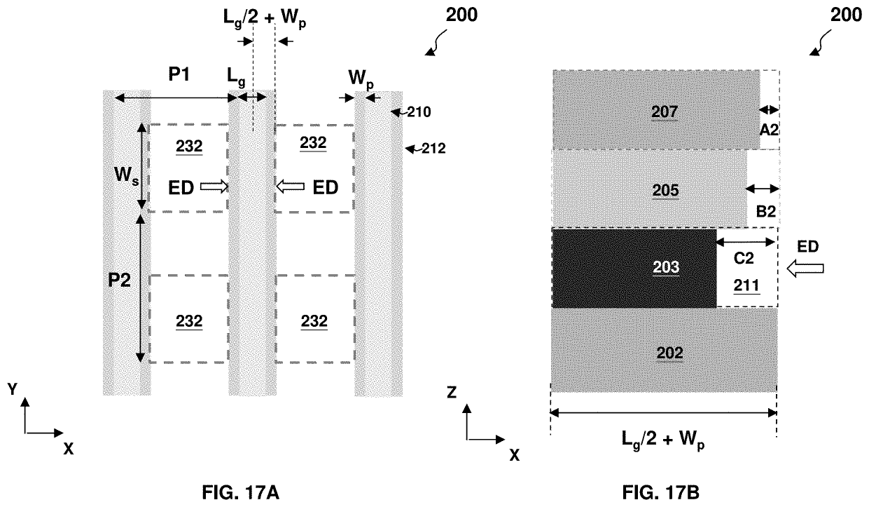

In the present embodiments, referring to FIGS. 16A and 17A, the etching process 312 is configured to remove the SiGe layer 203 isotropically from two opposite directions ED along the X axis. In other words, the SiGe layer 203 is removed from both sides of the dummy gate stack 210 (and the top gate spacers 212). In this regard, referring to FIGS. 17A-17B, a width C2 of the opening 211 is the sum of about half of the gate length L_{g} and the width Wₚ (i.e., (L_{g}/2+Wₚ)) measured along the X axis. Furthermore, the etching process 312 may inadvertently remove, though unsubstantially, portions of the SiGe layers 207 and the Si layers 205. As depicted in FIG. 17B, the amount removed from the SiGe layer 207 may be defined by a width A2 and the amount removed from the Si layer 205 may be defined by a width B2, where the widths A2 and B2 are similar to (or substantially the same as) the widths A1 and B1, respectively. In some embodiments, the width B2 is less than or equal to about 1 nm. Accordingly, the etching selectivity between the Si layer 205 and the SiGe layer 207 is defined by a ratio B2/A2 and may be similar to the etching selectivity S1, and an etching selectivity S3 between the SiGe layer 203 and the SiGe layer 207 is defined by a ratio C2/B2. In a non-limiting example, because Wₛ/2 may be greater than (L_{g}/2+Wₚ), the etching selectivity S2 may be greater than the etching selectivity S3 when the widths B1 and B2 are substantially the same, such as both less than or equal to about 1 nm.

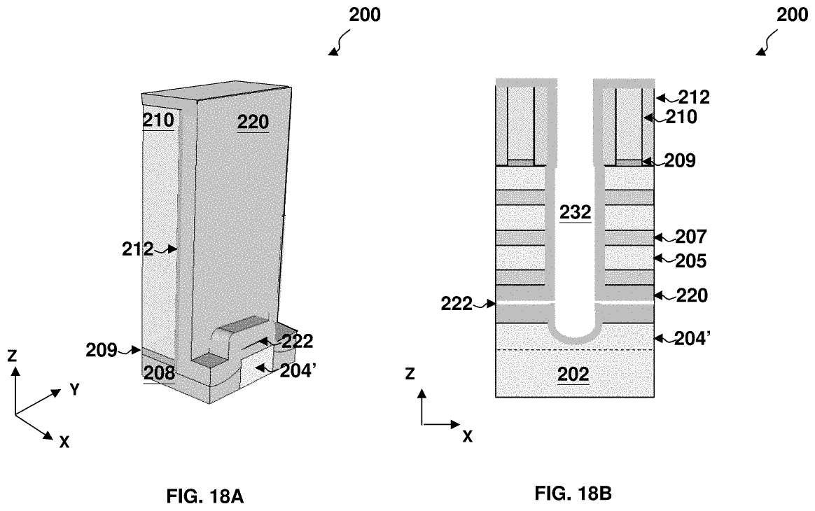

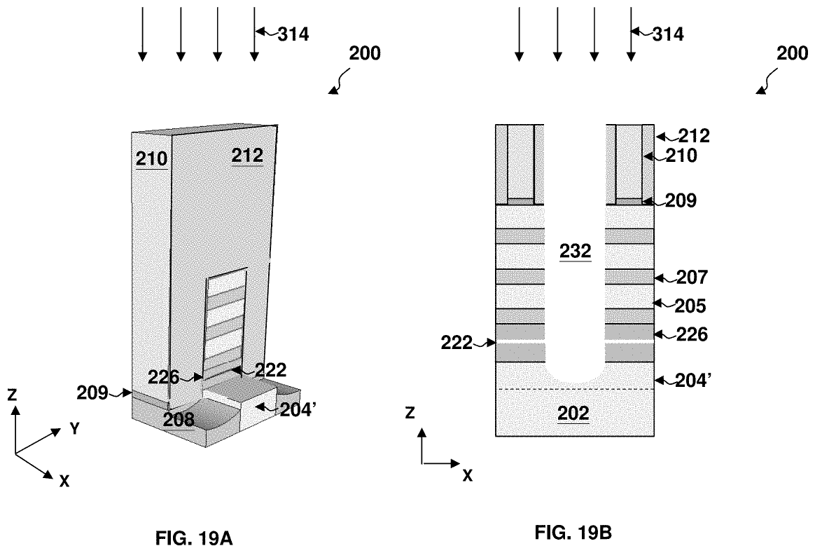

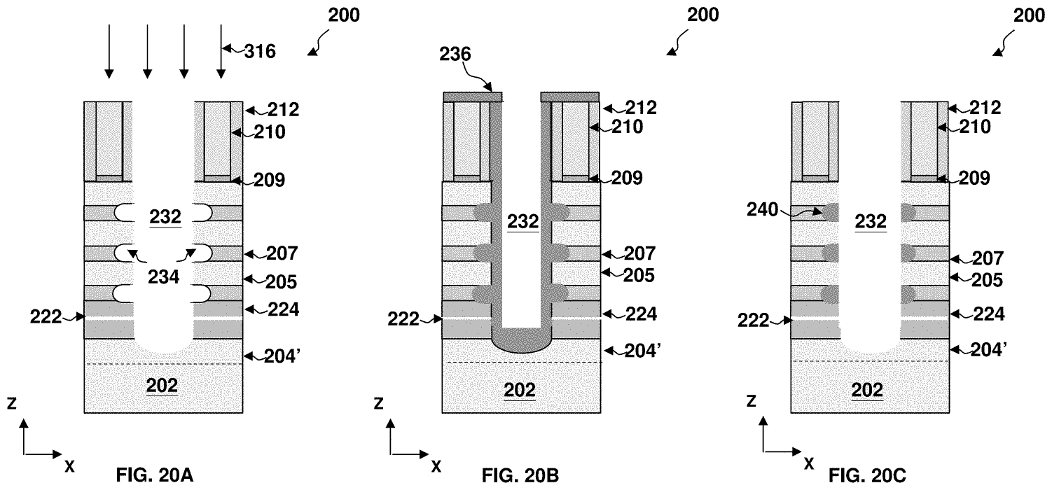

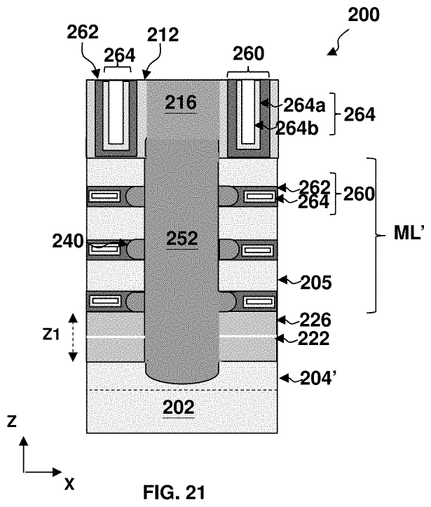

Now referring to FIGS. 1B and 18A-19B, method 140 at operation 149 forms the BDI 226 in the opening 211. Method 140 forms the BDI 226 in a series of processes similar to that discussed above with respect to operations 146 and 148. For example, referring to FIGS. 18A-18B, method 140 first deposits the dielectric layer 220 over the device 200, such that the dielectric layer 220 is formed over the top gate spacers 212, along sidewalls and bottom surface of the S/D recess 232, and in the opening 211. The composition and methods of forming the dielectric layer 220 are discussed in detail above. In some embodiments, as depicted herein, the seam 222 may be formed as a result of forming the dielectric layer 220 using, for example, an ALD process, though the seam 222 may not necessarily be present. In the depicted embodiments in FIGS. 18A-19B, the seam 222 extends in a substantially horizontal direction along the X axis.

Subsequently, referring to FIGS. 19A-19B, method 140 performs an etching process 314 to remove portions of the dielectric layer 220, leaving the BDI 226 in the opening 211. In the present embodiments, the etching process 314 is configured to remove portions of the dielectric layer 220 from the dummy gate stack 210, sidewalls of the top gate spacers 212, and sidewalls of the S/D recess 232, leaving a portion of the dielectric layer 220 in the opening 211 to form the BDI 226. In some embodiments, the etching process 314 is implemented in an anisotropic, or directional, manner. Because forming the S/D recess 232 removes the portion of the SiGe layer 203 disposed over the S/D region of the fin 204 at operation 145, the resulting BDI 226 is considered a “partial” BDI for the same reason discussed above.

Referring to FIGS. 20A-20C, method 140 at operation 151 forms the inner spacers 240 on the sidewalls of the SiGe layers 207 exposed in the S/D recess 232. In the present embodiments, method 140 implements an etching process 316, which may be similar to the etching process 306, to form the recesses 234, deposits the dielectric layer 236 over the device 200, and removes portions of the dielectric layer 236 to form the inner spacers 240 in the recesses 234 in a series of processes similar to those discussed above with respect to operation 156.

Thereafter, referring to FIGS. 1A and 21, method 100 proceeds to forming the epitaxial S/D feature 252 in the S/D recess 232 at operation 110 and subsequently forming the metal gate structure 260 at operations 112 and 114 as discussed in detail above with respect to FIGS. 13 and 14. It is noted that the embodiment of the device 200 depicted in FIG. 21 is similar to that depicted in FIG. 14, where the inner spacers 240 and the BDI 226 are formed by separate processes and may include, though not necessarily so, different materials.

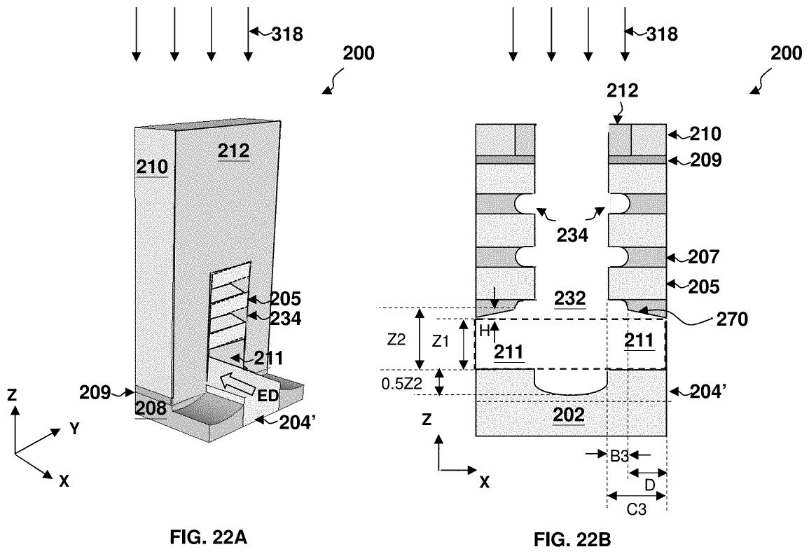

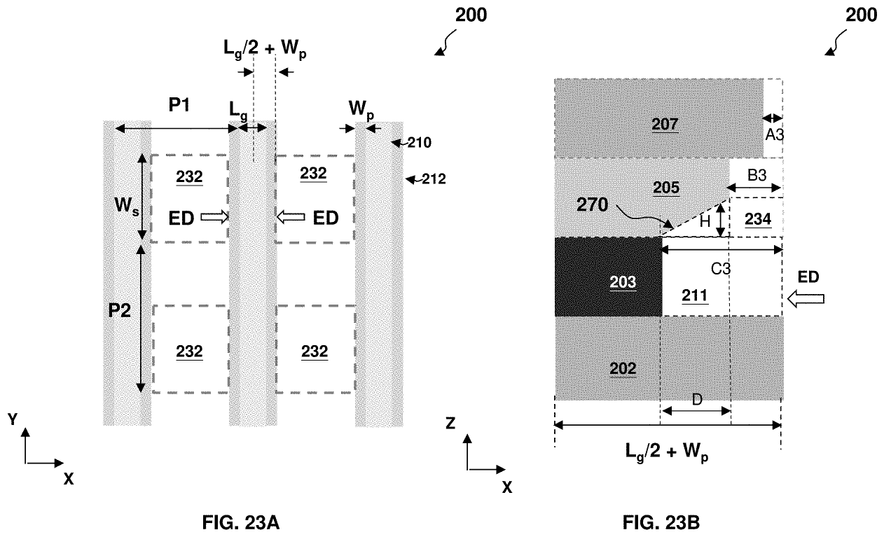

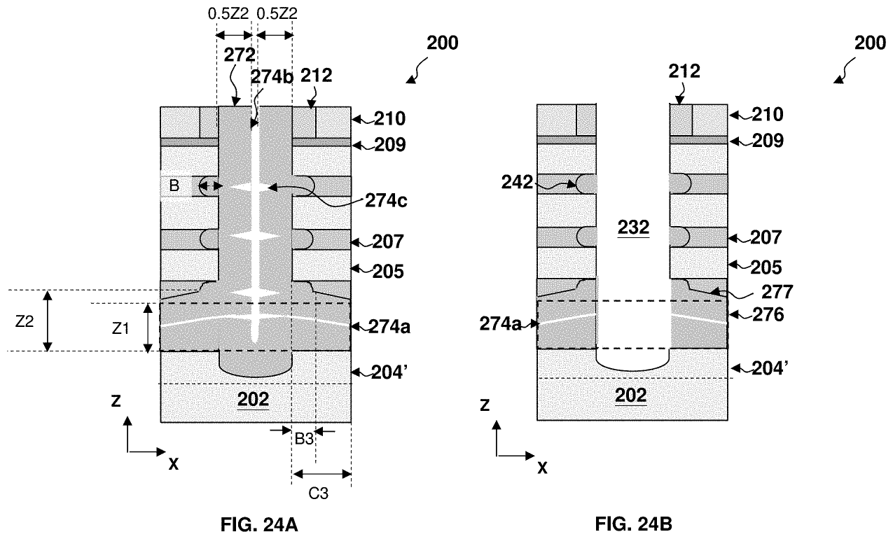

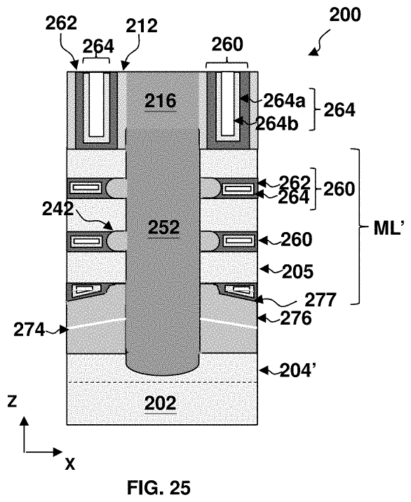

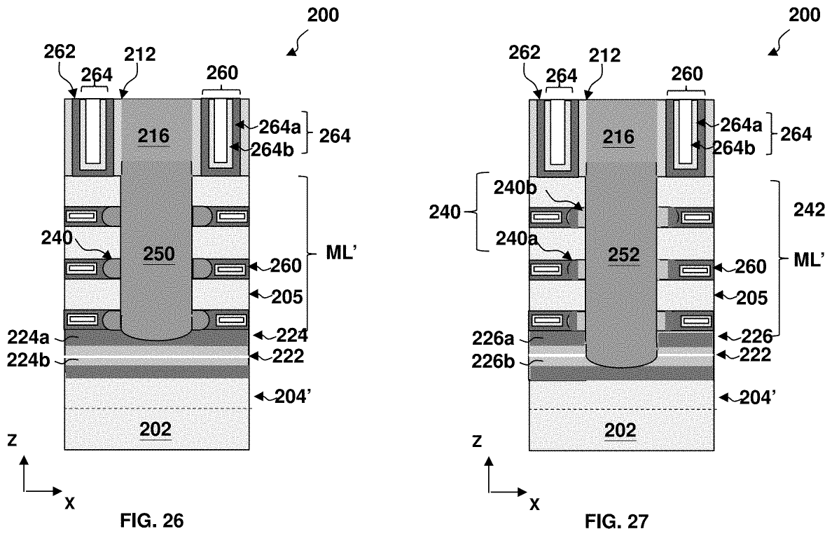

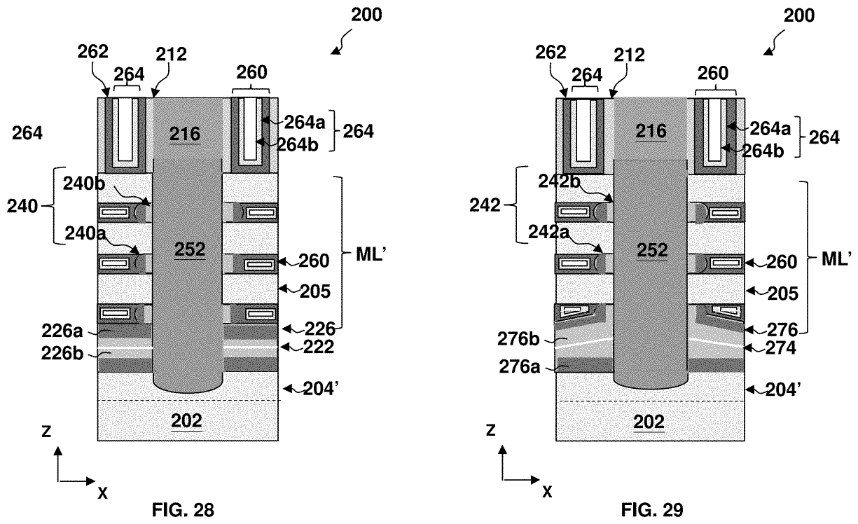

Alternative to operation 147, referring to FIGS. 22A-23B, method 140 at operation 153 removes the SiGe layer 203 and portions of the SiGe layers 207 in an etching process 318 to form the opening 211 and the recesses 234, where the recesses 234 are configured to form inner spacers in subsequent operations. Similar to the embodiment depicted in FIG. 17A, referring to FIG. 23A, the etching process 318 removes the SiGe layer 203 across a distance substantially equivalent to the sum of about half of the gate length L_{g} and the width Wₚ of the top gate spacers 212 (i.e., (L_{g}/2+Wₚ)).

In the present embodiments, the etching process 318 is configured to completely remove the SiGe layer 203 while also partially removing the SiGe layers 207. In contrast, the etching processes 302 and 312 implemented at operations 144 and 147, respectively, are configured to completely remove the SiGe layer 203 without removing, or substantially removing, the SiGe layers 207. In other words, an etching selectivity S4 between the SiGe layer 203 and the SiGe layers 207 configured for the etching process 318 is less than the etching selectivity S2 and S3 configured for the etching processes 302 and 312, respectively. In this regard, instead of forming the opening for the BDI and the recesses for the inner spacers separately (e.g., via the etching processes 312 and 316), method 140 at operation 153 may do so in a one-step etching process using the same etchant(s). Such reduced etching selectivity lowers the requirement for the amount of Ge in the SiGe layer 203 with respect to the SiGe layers 207, thereby resulting in less structural defects (e.g., lattice mismatch at an interface between the SiGe layer 203 and the bottommost SiGe layer 207) during the epitaxial formation of the ML. In some embodiments, the etching process 318 may be implemented isotropically and may include a dry etching process, a wet etching process, an RIE process, other suitable processes, or combinations thereof.

Still referring to FIGS. 22B and 23B, the opening 211 may be defined by a width C3 along the X axis and a height Z1 along the Z axis, and the recess 234 may be defined by a width B3 along the X axis, where the width B3 is also considered a lateral loss of the bottommost SiGe layer 207 during the etching process 318. Accordingly, the etching selectivity S4 between the SiGe layer 203 and the SiGe layers 207 may be expressed as a ratio C3/B3. In some embodiments, the specific value of the etching selectivity S4 is dependent on the value of the width B3, which determines the thickness of the inner spacers 242 formed in the recesses 234. In the present embodiments, the width B3 is configured to be greater than about 1 nm to about 5 nm. This is in contrast to the etching processes 302 and 312, in which the lateral losses defined by the widths B1 and B2, respectively, may be equal to or less than about 1 nm. If the width B3 is less than about 1 nm, the resulting inner spacers (i.e., the inner spacers 242) may be too thin to provide insulation between the metal gate structure (i.e., the metal gate structure 260) and the epitaxial S/D feature (i.e., the epitaxial S/D feature 252). If the width B3 is greater than about 5 nm, the resulting gate length L_{g} may be too small to meet the design requirement for a functional FET. In the present embodiments, for a width B3 that is between about 1 nm to about 5 nm, the etching selectivity S4 is about 2.4 to about 12, which is lower than the etching selectivity S2 and the etching selectivity S3 described previously. In some embodiments, the etching selectivity S4 is about 6 to about 12.

In the present embodiments, the relatively lower value of the etching selectivity S4 is responsible for the vertical over-etching of the bottommost SiGe layer 207 that results in a tapered opening 270 as depicted in FIGS. 22B and 23B. The tapered opening 270 may be defined by a width D that is a difference between the width C3 and the width B3. Additionally, a height H of the tapered opening 270, which is also considered a height loss of the bottommost SiGe layer 207, may be defined by a difference between a height Z2, which is a distance measured from a top surface of the tapered opening 270 to a bottom surface of the opening 211, and the height Z1. In this regard, a slope R of the tapered opening 270, which slants downward and away from the S/D recess 232, may be defined by the ratio H/D. In some embodiments, the height H is similar to the width B3, which is greater than about 1 nm but does not exceed about 5 nm. In contrast, the vertical over-etching of the SiGe layer 207 along the Z axis during the etching processes 302 and 312 is inconsequential compared to the isotropic etching of the SiGe layer 203. For example, though not depicted, the height loss resulting from the etching processes 302 and 312 depicted in FIGS. 5B and 16B is at most about 1 nm. In some non-limiting examples, referring to FIG. 22B, the width B3 may be about half of the height Z2 and a portion of the S/D recess 232 that extends into the base fin 204′ may be defined by a height of about half of the height Z2.

In the present embodiments, considerations for tuning the etching selectivity S4 between the SiGe layer 203 and the SiGe layers 207 for the etching process 318 are two-fold. Firstly, the etching selectivity S4 should be sufficiently high to ensure that the SiGe layer 203 is etched substantially more than the SiGe layers 207. Secondly, the etching selectivity S4 should not exceed a threshold value to ensure that the resulting inner spacers (i.e., inner spacers 242 depicted in FIG. 24B) are formed to a sufficient thickness for providing insulation in the device 200.

In some embodiments, tuning the etching selectivity S4 may be achieved by using etchants that are different from those utilized for the etching processes 302 and 312. Alternatively or additionally, tuning the etching selectivity S4 may be achieved by decreasing the amount y of Ge in Si_{1-y}Ge_{y} of the SiGe layer 203, though the value of y remains greater than the value of x but less than about 0.6 (60%) as discussed in detail above.

Referring to Table 2 below, applicability of the same example etchants, namely Etchant 1, Etchant 2, Etchant 3, and Etchant 4, as those listed in Table 1 for the etching process 302 are provided. The symbol “#” indicates that usage of the example etchant is not applicable for achieving the target range of etching selectivity S4 according to the considerations stated above. For example, Etchant 1, which is applicable for yielding a relatively higher etching selectivity (i.e., the etching selectivity S2) for the etching process 302, may not sufficiently etch both the SiGe layer 203 and the SiGe layers 207 during the etching process 318 when the amount of Ge in the SiGe layer 203 exceeds about 30%. In contrast, Etchant 3 and Etchant 4, alone or in combination, are applicable for achieving the desired range of etching selectivity S4 when the amount of Ge in the SiGe layer 203 exceeds about 30%. It is noted that the present disclosure is not limited by the content of Table 2, which is provided for purposes of illustration only.

TABLE 2

| | | Etchant 2 | | |
|---|---|---|---|---|
| | Etchant 1 | 1:2:3 (20%-50% | | |
| | 1:1 (28% | HF):(30% | Etchant 3 | Etchant 4 |
| | NH₄OH):(31% | H₂O₂):(99.5% | Plasmaless | Gaseous |
| | H₂O₂) | CH₃COOH) | ClF₃ | HCl |
| x~0.15-0.3 | # | | | |
| y ≥ 0.3 | | | | |
| x~0.15-0.3 | # | # | | |
| y ≥ 0.4 | | | | |
| x~0.15-0.3 | # | # | | |
| y ≥ 0.5 | | | | |

Subsequently, referring to FIGS. 1B and 24A, method 140 at operation 155 deposits a dielectric layer 272 over the device 200, thereby filling the S/D recess 232, the opening 211, the tapered opening 270, and the recesses 234. The dielectric layer 272 may be substantially similar to or different from the dielectric layer 220 discussed above and may include any suitable material, such as silicon oxide, silicon nitride, carbon-containing silicon nitride (SiCN), carbon-containing silicon oxide (SiOC), oxygen-containing silicon nitride (SiON), carbon-and-oxygen-doped silicon nitride (SiOCN), a low-k dielectric material, other suitable dielectric material, or combination thereof. The dielectric layer 272 may be deposited by any suitable method, such as ALD, CVD, other suitable methods, or combinations thereof. In the present embodiments, the dielectric layer 272 is deposited by an ALD process.

In some embodiments, forming the dielectric layer 272 in the opening 211 using the ALD process results in a seam, or an air gap, 274a extending lengthwise along the X axis. The seam 274a differs from the seam 222 in that the seam 274 is configured to have a slope equal to or less than the slope R of the tapered opening 270 depicted in FIGS. 22B and 23B. Referring to FIG. 24A, forming the dielectric layer 272 may result in additional seams 274b and 274c, where the seam 274 extends generally along the Z axis and the seams 274c each extend away from the seam 274b along the X axis. In some embodiments, a height of the seam 274c measured along the Z axis gradually decreases in a direction away from the seam 274b and along the X axis. In some examples, a portion of the dielectric layer 272 formed on each side of the seam 274b may be defined by a thickness that is about half of the height Z2 as depicted in FIG. 24A. In some embodiments, one or more of the seams 274a-274c are absent from the device 200 following the deposition process at operation 155. It is noted that after trimming the dielectric layer 272 in a subsequent etching process, the seams 274b and 274c, if present, are removed from the device 200.

Referring to FIGS. 1B and 24B, method 140 at operation 157 performs an etching (or trimming) process to remove portions of the dielectric layer 272 formed in the S/D recess 232, leaving portions of the dielectric layer 272 in the opening 211 and the tapered opening 270 to form a BDI 276 and in the recesses 234 to form the inner spacers 242. Notably, after removing the portions of the dielectric layer 272, portions of the seam 274a remain in the BDI 276. In some embodiments, the etching process is similar to the etching process 314 discussed in detail above with respect to operation 148. The resulting BDI 276 includes a tapered upper surface 277 extending downwardly and away from the S/D recess 232.

Referring to FIGS. 1A and 25, method 100 proceeds to forming the epitaxial S/D feature 252 in the S/D recess 232 at operation 110 and subsequently replacing the dummy gate stack 210 and the remaining portions of the SiGe layers 207 with the metal gate structure 260 at operations 112 and 114, as discussed in detail above with respect to FIGS. 13 and 14.

In the present embodiments, the differences between the device 200 depicted in FIG. 25 and that depicted in FIGS. 13 and 14 (or 21) are two-fold. Firstly, the inner spacers 242 and the BDI 276 depicted in FIG. 25 are formed by common etching and deposition processes, such that they may be formed to have the same composition. In contrast, the inner spacers 240 and the BDI 226 depicted in FIGS. 13 and 14 could be formed to have different compositions as they are formed in separate processes. Secondly, the common etching process for forming the inner spacers 242 and the BDI 276 causes over-etching in the bottommost SiGe layer 207 of the ML, resulting in the BDI 276 to have a downwardly tapered upper surface 277 that interfaces with the bottommost SiGe layer 207. In the present embodiments, the tapered upper surface 277 also interfaces with the bottommost portion of the metal gate structure 260. In contrast, the upper surface of the BDI 224 and the BDI 226 depicted in FIGS. 13 and 14 is substantially horizontal along the X axis. In the present embodiments, the seam 274a is also defined by a downward slope that may be less than or equal to the slope R of the tapered upper surface 277 of the BDI 276.

In some embodiments, referring to FIGS. 26-29, which correspond to FIGS. 13, 14A, 14B, and 25, respectively, the BDIs 224 (FIGS. 26 and 27), 226 (FIG. 28), and 276 (FIG. 29) are configured with multiple layers of different dielectric materials. For example, the BDI 224 may include a layer 224b disposed over a layer 224a, the BDI 226 may include a layer 226b over a layer 226a, and the BDI 276 may include a layer 276b over a layer 276a. In some embodiments, referring to FIG. 26, the inner spacers 240 may include a single-layer structure and the BDI 224 includes a multi-layer structure. In some embodiments, referring to FIGS. 27 and 28, the inner spacers 240 includes a layer 240b disposed over a layer 240a in a multi-layer structure, where the layers 240a and 240b may be the same as or different from the layers 226a and 226b, respectively. In some embodiments, referring to FIG. 29, the inner spacers 242 includes a layer 242b disposed over a layer 242a in a multi-layer structure, where the layers 242a and 242b are the same as the layers 276a and 276b, respectively. Examples of the dielectric materials included in the layers 224a, 224b, 226a, 226b, 240a, 240b, 242a, 242b, 276a, and 276b are discussed above with respect to the dielectric layer 220 and the inner spacers 240.

Thereafter, method 100 at operation 116 may perform additional processing steps to the device 200. For example, method 100 may form S/D contacts (not depicted) over the epitaxial S/D features 250 (or 252). Each S/D contact may include any suitable conductive material, such as Co, W, Ru, Cu, Al, Ti, Ni, Au, Pt, Pd, other suitable conductive materials, or combinations thereof. Method 100 may form an S/D contact opening in the ILD layer 216 via a series of patterning and etching processes and subsequently deposit a conductive material in the S/D contact opening using any suitable method, such as CVD, ALD, PVD, plating, other suitable processes, or combinations thereof. In some embodiments, a silicide layer (not depicted) is formed between the epitaxial S/D features 250 (or 252) and their respective S/D contacts. The silicide layer may include nickel silicide, cobalt silicide, tungsten silicide, tantalum silicide, titanium silicide, platinum silicide, erbium silicide, palladium silicide, other suitable silicide, or combinations thereof. The silicide layer may be formed over the device 200 by a deposition process such as CVD, ALD, PVD, or combinations thereof. Subsequently, though not depicted, method 100 may form additional features over the device 200, such as additional ESLs and ILD layers, a gate contact over the metal gate structure 260, vertical interconnect features (e.g., vias), horizontal interconnect features (e.g., conductive lines), additional intermetal dielectric layers (e.g., ESLs and ILD layers), other suitable features, or combinations thereof.

Although not intended to be limiting, one or more embodiments of the present disclosure provide many benefits to a semiconductor device and the formation thereof. For example, the present disclosure provides methods of forming a GAA FET including a bottom (or buried) dielectric isolation structure (BDI) that may extend under a channel region or under both the channel and S/D regions of the GAA FET. In the present embodiments, forming the BDI includes forming a dummy SiGe layer and subsequently replacing it with a dielectric layer to form the BDI. In some embodiments, the BDI is formed in a BDI-first process before forming an S/D recess. Alternatively, the BDI is formed in a BDI-last process after forming the S/D recess. In some embodiments, the BDI and inner spacers of the GAA FET are formed together in a series of etching and deposition processes. In some embodiments, the BDI is formed to include a tapered top surface that interfaces with a bottommost portion of a gate structure of the GAA FET. Embodiments of the present disclosure may be suitable for improving control of sub-channel leakage by incorporating a buried dielectric layer under the channel and/or S/D regions of a GAA FET.

In one aspect, the present disclosure provides a semiconductor structure that includes a substrate and a plurality of semiconductor layers disposed over the substrate. The semiconductor structure also includes a gate structure disposed on and wrapping each of the semiconductor layers and a source/drain feature disposed over the substrate and adjacent the gate structure. The semiconductor structure further includes a dielectric layer disposed between a bottommost surface of the gate structure and the substrate.

In another aspect, the present disclosure provides a semiconductor structure that includes a substrate and a stacked structure including channel layers interleaved with a metal gate structure. The semiconductor structure also includes an isolation feature disposed between the stacked structure and the substrate, where a bottommost portion of the metal gate structure directly contacts the isolation feature. The semiconductor structure further includes a source/drain feature disposed adjacent the stacked structure and an inner spacer disposed between the metal gate structure and the source/drain feature.

In yet another aspect, the present disclosure provides a method that includes forming a fin protruding from a substrate, where the fin includes a first SiGe layer and a stacked structure over the first SiGe layer, where the stacked structure includes alternating second SiGe layers and Si layers, and where the first SiGe layer includes more Ge than each of the second SiGe layers; forming a dummy gate stack over a channel region of the fin; replacing the first SiGe layer with a dielectric layer to form an isolation feature; removing a portion of the fin to form a source/drain recess adjacent the dummy gate stack; forming inner spacers on sidewalls of the second SiGe layers exposed in the source/drain recess; forming a source/drain feature over the inner spacers; and forming a metal gate structure adjacent the source/drain feature to replace the dummy gate stack and the second SiGe layers, such that a bottommost portion of the metal gate structure directly contacts the isolation feature.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a plurality of semiconductor layers disposed over the substrate;
a gate structure disposed on and wrapping each of the semiconductor layers;
a source/drain feature disposed over the substrate and adjacent the gate structure; and
a dielectric layer disposed between a bottommost surface of the gate structure and the substrate.

2. The semiconductor structure of claim 1, wherein the dielectric layer includes a first portion disposed between the bottommost surface of the gate structure and the substrate and a second portion disposed between the source/drain feature and the substrate.

3. The semiconductor structure of claim 1, wherein the dielectric layer includes a seam embedded therein.

4. The semiconductor structure of claim 3, wherein the source/drain feature extends to below the seam but above the substrate.

5. The semiconductor structure of claim 1, wherein the dielectric layer includes a tapered top surface extending downward from the source/drain feature.

6. The semiconductor structure of claim 5, wherein the dielectric layer includes a seam embedded therein, and wherein the seam is tapered.

7. The semiconductor structure of claim 1, further comprising an inner spacer between the gate structure and the source/drain feature, wherein the inner spacer and the dielectric layer have the same composition.

8. A semiconductor structure, comprising:
a substrate;
a stacked structure including channel layers interleaved with a metal gate structure;
an isolation feature disposed between the stacked structure and the substrate, wherein a bottommost portion of the metal gate structure directly contacts the isolation feature;
a source/drain feature disposed adjacent the stacked structure; and
an inner spacer disposed between the metal gate structure and the source/drain feature.

9. The semiconductor structure of claim 8, wherein the source/drain feature extends through the isolation feature to contact the substrate.

10. The semiconductor structure of claim 8, wherein a bottom surface of the source/drain feature directly contacts the isolation feature.

11. The semiconductor structure of claim 8, wherein an interface between the bottommost portion of the metal gate structure and the isolation feature is slanted downward.

12. The semiconductor structure of claim 8, wherein the inner spacer and the isolation feature have the same composition.

13. The semiconductor structure of claim 8, wherein the isolation feature encloses an air gap.

14. A method, comprising:
forming a fin protruding from a substrate, wherein the fin includes a first SiGe layer and a stacked structure over the first SiGe layer, wherein the stacked structure includes alternating second SiGe layers and Si layers, and wherein the first SiGe layer includes more Ge than each of the second SiGe layers;
forming a dummy gate stack over a channel region of the fin;
replacing the first SiGe layer with a dielectric layer to form an isolation feature;
removing a portion of the fin to form a source/drain recess adjacent the dummy gate stack;
forming inner spacers on sidewalls of the second SiGe layers exposed in the source/drain recess;
forming a source/drain feature over the inner spacers; and
forming a metal gate structure adjacent the source/drain feature to replace the dummy gate stack and the second SiGe layers, such that a bottommost portion of the metal gate structure directly contacts the isolation feature.

15. The method of claim 14, wherein the source/drain recess is formed after forming the isolation feature.

16. The method of claim 15, further comprising, after forming the source/drain recess, removing a portion of the isolation feature in the source/drain recess to expose the substrate, such that a bottom surface of the source/drain feature is formed to directly contact the substrate.

17. The method of claim 15, wherein forming the source/drain recess exposes a portion of the isolation feature in the source/drain recess, such that a bottom surface of the source/drain feature is formed to directly contact the isolation feature.

18. The method of claim 14, wherein forming the source/drain recess is performed before forming the isolation feature, and wherein forming the inner spacers is performed after forming the isolation feature.

19. The method of claim 14, wherein forming the source/drain recess is performed before forming the isolation feature, and wherein replacing the first SiGe layer includes forming the isolation feature and forming the inner spacers together.

20. The method of claim 14, wherein replacing the first SiGe layer includes:
selectively removing the first SiGe layer with respect to the second SiGe layers and the Si layers to form an opening;
depositing the dielectric layer over the substrate, thereby filling the opening; and
performing an anisotropic etching process to remove a portion of the dielectric layer, leaving the isolation feature in the opening.
